(19) United States
(12) Patent Application Publication
(10) Pub. No.: US 2023/0304141 A1
(43) Pub. Date: Sep. 28, 2023

(54) METHOD OF FORMING A CATHODE LAYER, METHOD OF FORMING A BATTERY HALF CELL

(71) Applicant: Dyson Technology Limited, Wiltshire (GB)

(72) Inventors: Samuel John ALEXANDER, Gloucester (GB); Robert Ian Joseph GRUAR, Swindon (GB)

(73) Assignee: Dyson Technology Limited, Wiltshire (GB)

(21) Appl. No.: 18/020,412

(22) PCT Filed: Aug. 10, 2021
(86) PCT No.: PCT/GB2021/052067

§ 371 Date: Feb. 8, 2023

(30) Foreign Application Priority Data
Aug. 13, 2020 (GB) 2012668.6

(51) Int. Cl. C23C 14/34; H01M 4/04; C23C 14/08

(52) U.S. Cl. CPC C23C 14/345; H01M 4/0426; C23C 14/3464; C23C 14/085; H01M 2004/028

(57) ABSTRACT

A method of forming a layer of a cathode is provided. The method includes generating a plasma remote from one or more sputter targets, sputtering material from the target or targets using the plasma, and depositing the sputtered material on the substrate to which a bias voltage has been applied, thereby forming the layer of cathode.

### BACKGROUND OF THE INVENTION

The present disclosure relates to methods of forming layers of cathode, such as those used in solid-state battery cells.

The present invention concerns methods of forming layers of cathode. More particularly, but not exclusively, this invention concerns a method of forming layer of cathode on a substrate, a method of forming a (crystalline) cathode layer of a solid-state battery, a method of forming a solid state battery half-cell, a method of forming a solid state battery cell and a method of forming a solid state battery. The invention also concerns a method of determining a function which describes the crystallinity of a layer of cathode of material, a method of determining a function which describes the phase distribution of a layer of cathode of material, and a method of determining the voltage bias at which a high energy crystal structure would be present in a layer of cathode of material, The invention also concerns solid state battery half-cells, solid state battery cells and solid state batteries made in accordance with such methods.

Solid state batteries comprise a cathode material. Such materials are often high energy crystal structures, and often lithium-ion containing materials, such as LiCoO₂. These high energy crystal structures may be deposited using plasma deposition techniques, but typically require annealing in order to produce a crystalline material which is used as a cathode material. The annealing process typically involves heating the high energy crystal structure (optionally a lithium-containing material) to temperatures of about 400° C., and in the case of some high energy crystal structures, 600° C. This requires significant energy and exposes any other materials associated with the high energy crystal structure, such as underlying substrates, to such temperatures, which may not be desirable.

The present invention seeks to mitigate the above-mentioned problems. Alternatively or additionally, the present invention seeks to provide an improved method of forming a layer of cathode on a substrate.

### SUMMARY OF THE INVENTION

In accordance with a first aspect of the present invention, there is provided a method of forming a layer of a cathode, optionally for a solid-state battery, on a substrate, the method comprising:

generating a plasma remote from one or more sputter targets, sputtering material from the target or targets using the plasma, and depositing the sputtered material on the substrate, to which a bias voltage has been applied thereby forming the layer of cathode.

The applicant has discovered that it is possible to form films of cathode material directly onto substrates. In “directly”, what is meant is that the film forms a film with substantially no annealing step. The method has been shown to work on a wide range of substrate materials. The applicant has discovered that the method is particularly effective for depositing crystalline alkali and alkaline earth metal-based cathode materials, such as lithium-based cathode layers.

The layer of cathode is optionally crystalline.

The applicant has discovered that it is possible to deposit a layer of cathode of a solid-state thin-film device in crystalline form onto a substrate without having to anneal the layer post-deposition. Furthermore, annealing may involve heating to temperatures which are not tolerated by some substrates, such as polymer substrates the structural integrity of which may be compromised by heating to annealing temperatures.

The plasma is generated remotely from the plasma target(s). In conventional plasma deposition, a target is required to produce and sustain the plasma.

The solid-state thin-film device may be a solid-state battery.

As stated in the background of invention, high energy crystal structures may be deposited using plasma deposition techniques, but typically require annealing in order to produce a crystalline material which is used as a cathode material. In certain lithium-containing materials, the annealing process typically involves heating the lithium-containing material to temperatures of about 400° C., in the case of some high energy crystal structures, 600° C. This requires a lot of energy and exposes any other materials associated with the high energy crystal structure, such as underlying substrates, to such temperatures which may not be desirable.

The applicant has discovered that it is possible to deposit a cathode layer of a solid state battery in crystalline form onto a substrate without having to anneal the cathode layer post-deposition. The applicant has also discovered that the application of a bias voltage to the substrate may improve the crystallinity of the deposited layer. The bias voltage may be applied directly to the substrate

The applicant has discovered that applying a bias to the substrate may be beneficial in depositing crystalline materials without the need to anneal the material so deposited. The method may take place with substantially no annealing needed to form a high energy crystal structure. The voltage may be applied to the substrate directly, for example by contacting the substrate with a connection from an RF power generation device. The voltage bias may alternatively be applied to the substrate indirectly, for example, in the region of the substrate, such that the RF energy propagates to the substrate material, resulting in the voltage bias being applied to the substrate. The voltage bias may be indirectly applied to the substrate by it being applied to a platform on which the substrate rests. The voltage bias may be indirectly applied to the substrate by it being applied to a charged element or plate placed proximal to the substrate.

The voltage bias to the substrate is optionally negatively charged. Without wishing to be bound by theory, it is believed that a voltage bias applied to the substrate results in positively charged sputtered material being attracted towards the substrate, so that the material arrives at the substrate with a high ad atom energy. This results in there being more energy for crystallisation to occur during the depositing of material into the substrate.

The voltage bias to the substrate is optionally provided by a Radio Frequency (RF) generator. The use of an RF generator helps prevent charge building up on the surface of the substrate, which would impede the deposition of material onto the substrate. For the avoidance of doubt, the term “to which a bias voltage has been applied” also includes the scenario where a bias voltage is applied to a support on which the substrate is resting. Such an arrangement generates an electrical field that attracts ions to the substrate.

Typically, the power is defined as the output power used to generate the bias voltage. It will be known and accepted by the person skilled in the art that the output power used to generate the bias voltage may be dependent on the efficiency of the device that generates said voltage. Thus, the skilled person would know that the values of power, power density or voltage described herein assume a device with an average power generation efficiency, and that the values herein should be adjusted accordingly should a particularly efficient, or inefficient device be used to generate the voltage bias on the substrate.

The power density is defined by dividing the output power used to generate the bias voltage by the surface area of the substrate.

The power density associated with the voltage bias of the substrate may be greater than N*X Wcm⁻², wherein N is a normalisation factor that is selected in view of one or more process parameters of the method, and X is a value of power density, optionally from 1 Wcm⁻² to 4 Wcm⁻². The power density associated with the voltage bias on the substrate may be a normalised power density. A normalised power density has had the normalisation factor applied to it.

The (optionally normalised) power density associated with the voltage bias of the substrate may be at least 0.1 Wcm⁻², optionally at least 0.2 Wcm⁻², optionally at least 0.3 Wcm⁻², and optionally at least 0.5 Wcm⁻²; It has unexpectedly been found that applying a bias voltage to the substrate, optionally at a (optionally normalised) power density of at least 0.5 Wcm⁻² unexpectedly causes an increase in crystallinity of the deposited cathode layer, compared to the crystallinity of a cathode layer deposited where there is no bias applied to the substrate. It has been shown that, for some materials at least, the degree of crystallinity of the sample increases with the voltage bias applied to the substrate. The degree of crystallinity may increase linearly with the voltage bias applied to the substrate. Optionally, the (optionally normalised) power density associated with the voltage bias of the substrate is at least 0.5 Wcm⁻², optionally at least 1.0 Wcm⁻², optionally at least 1.5 Wcm⁻² and optionally at least 1.9 Wcm⁻².

Optionally, the (optionally normalised) power associated with the voltage bias applied is optionally at least 100 W, optionally at least 150 W, optionally at least 300 W and optionally at least 350 W.

The (optionally normalised) power density associated with the voltage bias of the substrate may be at least 1.0 Wcm⁻²; it has unexpectedly been found that applying a (optionally normalised) power density associated with the voltage bias on the substrate at least 1.0 Wcm⁻² may promote the formation of higher energy phases in the layer of cathode deposited. It has been shown that at least some of the layer of cathode material transitions from a low energy crystal structure to a high energy crystal structure when a sufficiently large bias is applied to the substrate. The amount of the high energy crystal structure present in the cathode layer may increase suddenly above a certain (or critical) power density value. Optionally, the (optionally normalised) power density associated with the voltage bias of the substrate is optionally at least 1.0 Wcm⁻², optionally at least 1.9 Wcm⁻², optionally at least 2.3 Wcm⁻² optionally at least 2.8 Wcm⁻² and optionally greater than 3.4 Wcm⁻².

Optionally, the power associated with the voltage bias applied to the substrate is at least 150 W, optionally at least 350 W, optionally at least 400 W, optionally at least 450 W and optionally at least 600 W.

The value of X, the power density, is optionally no more than 4.0 Wcm⁻², optionally no more than 3.0 W cm⁻² and optionally no more than 2.8 Wcm⁻². The value of X may be from 1.0 Wcm⁻² to 4.0 Wcm⁻², optionally from 1.5 Wcm⁻² to 3.8 Wcm⁻², and optionally from 1.8 Wcm⁻² to 3.4 Wcm⁻².

Without wishing to be bound by theory, it is understood that the voltage bias applied to the substrate is a contribution to the overall arrival energy (in other words a contribution to the ad atom energy) of the sputtered material as it reaches the substrate. The contribution from the voltage bias as atoms/ions/material arrives at the substrate may be considered to be the parameter, SBP. Other process parameters also affect the arrival energy of atoms/ions/material at the substrate. Such other processes parameters may include the following: the specific materials being deposited; the type and number of targets being used; the thicknesses of layers being deposited, and the thickness of layers that may have previously been deposited; the thickness and material of the substrates on to which material is being deposited, the power applied to the plasma source, the power applied to the targets, the process pressure of the deposition chamber or space in which deposition occurs, and the presence of any reactive gases in the sputtering process. Without wishing to be bound by theory, it is understood that the contributions of these parameters to the arrival energy of ions as they arrive at the substrate can be summarised as parameter OCP. Therefore, and once again without wishing to be bound by theory, the overall arrival energy (ArrE) can be expressed as ArrE=N*SBP+OCP, where N is a normalisation factor that may satisfy any value such that ArrE remains constant for differing OCP values (which are variable depending on different sputtering system configurations).

The power density associated with the voltage bias of the substrate is optionally no more 3 Wcm⁻².

The power density may be normalised, as previously described.

The applicant has discovered that when the power associated with the voltage bias of the substrate is above a certain value, unfavourable oxidation states of material may form on the substrate. For example, in the case where the material being sputtered is LiCoO₂, the unfavourable oxide that may form may be Co(II)O. Depending on the process parameters in the sputter deposition process, the oxides may form at different values of voltage bias applied to the substrate. In this connection, the (optionally normalised) value of the power density associated with the voltage bias on the substrate is optionally no more than 3.4 Wcm⁻², optionally no more than 2.5 Wcm⁻², optionally no more than 2.2 Wcm⁻² and optionally no more than 1.7 Wcm⁻². The value of the power associated with the voltage bias on the substrate is optionally no more than 600 W, optionally no more than 400 W and optionally no more than 300 W.

The applicant has also observed that the improvement in the properties of the deposited material by the application of the bias to the substrate, for example the improvement in the degree of crystallinity of the material, may level off at a certain voltage bias, at which the properties appear to improve no further. In examples where this may be the case, the power associated with the voltage bias is optionally no more than 600 W, optionally no more than 400 W and optionally no more than 350 W. The (optionally normalised) power associated with the voltage bias on the substrate is optionally no more than 2.8 Wcm⁻², optionally no more than 2.6 Wcm⁻², optionally no more than 2.3 Wcm⁻² and optionally no more than 2 Wcm⁻².

The power associated with the voltage bias of the substrate may optionally be less than the value at which material on the substrate would begin to be re-sputtered.

The power associated with the voltage bias of the substrate may be less than the value at which any alkali metal ions, such as lithium ions, present in the layer of cathode would begin to be re-sputtered.

One way of determining whether or not re-sputtering is occurring is to measure the deposition rate. If re-sputtering is occurring then the deposition rate will typically be lower than if re-sputtering is not occurring. It is expected that if the power density associated with the voltage is above a certain high value, then re-sputtering will occur and the deposition rate will be lower than expected. Optionally, there may, therefore, be an upper threshold limit for the power density associated with the voltage bias of the substrate above which re-sputtering occurs and deposition rates are expected to decrease.

The material on the substrate that may begin to be re-sputtered may be any alkali metal ions such as lithium ions present in the layer of cathode.

The layer of cathode optionally comprises an alkali metal-based (optionally lithium-based) material or an alkaline earth metal-based material.

The alkali metal, if present, may optionally be one or more of Li, Na, K, Cs and Rb, optionally one or more of Li, Na or K, optionally Li or Na and optionally Li. Lithium ions are sometimes used as conductive species in cathodes of solid state batteries. The alkaline earth metal, if present, may optionally be one or more of magnesium, calcium, strontium or barium, optionally one or more of magnesium, calcium and barium and optionally one or both of magnesium and calcium.

The layer of cathode optionally comprises at least one transition metal and a counter-ion.

The one or more transition metal may be in period 4 or period 5 of the Periodic Table. At least one, and optionally each, transition metal may optionally be selected from the group consisting of Fe, Co, Mn, Ni, Ti, Nb and V. The layer of cathode of material may comprise one or more alkali metal, one or more transition metal and (each of which is selected from the group consisting of Co, Ni, Mn, Fe, V, Nb and Ti, and optionally from the group consisting of Co, Ni and Mn), and optionally another metal not being an alkali metal or a transition metal (such as aluminium). The layer of cathode may be an oxide or phosphate, and may comprise lithium and at least one transition metal, and optionally more than one transition metal, each transition metal being selected from the group consisting of Co, Ni, Mn, Fe, V, Nb and Ti, and optionally from the group consisting of Co, Ni and Mn. The layer of cathode may be an oxide or phosphate, and may consist of oxygen (in the case of an oxide) or phosphate (in the case of a phosphate), in combination with lithium and at least one transition metal, and optionally more than one transition metal, each transition metal being selected from the group consisting of Co, Ni, Mn, Fe, V, Nb and Ti, and optionally from the group consisting of Co, Ni and Mn, and optionally aluminium.

The nature of the counter ion is not particularly important. The counter-ion optionally comprises one or more of PO₄, oxide, dioxide, borate and silicate.

The layer of cathode may comprise a post-transition metal, such as aluminium.

The layer of cathode is optionally an oxide, said oxide consisting essentially of oxygen, lithium, one or more of manganese, nickel and cobalt, and optionally aluminium.

The layer of cathode may be of empirical formula AₐM1_{b}M2_{c}O₂, wherein A is an alkali metal (optionally lithium), M1 is one or more transition metal (optionally one or more of cobalt, nickel, niobium, vanadium and manganese) (b being the total of transition metal), M2 being aluminium, a being from 0.5 to 1.5 and z being from 0 to 0.5.

Optionally, a is 1, b is 1 and c is 0. Optionally, M1 is one of cobalt, nickel, vanadium, niobium and manganese.

Optionally, a is more than 1 and A is lithium. In the case, the materials are sometimes known as “lithium rich” materials. Such lithium-rich materials may be

$$\text{?} {O}_{2}$$

$$\text{?} \text{indicates text missing or illegible when filed}$$

with x=0, 0.06, 0.12, 0.2, 0.3 and 0.4, for example

Another such material is

$$\text{?} {O}_{2}$$

$$\text{?} \text{indicates text missing or illegible when filed}$$

wherein y has a value greater than 0.12 and equal to or less than 0.4.

Another such material is

$$\text{?} {Co}_{y} \text{?} {O}_{2}$$

$$\text{?} \text{indicates text missing or illegible when filed}$$

x has a value equal to or greater than 0.175 and equal to or less than 0.325; and y has a value equal to or greater than 0.05 and equal to or less than 0.35.

$$\text{?} {Co}_{y} \text{?} {O}_{2}$$

$$\text{?} \text{indicates text missing or illegible when filed}$$

is another such material, wherein x is equal to or greater than 0 and equal to or less than 0.4; y is equal to or greater than 0.1 and equal to or less than 0.4; and z is equal to or greater than 0.02 and equal to or less than 0.3.

The layer of cathode is optionally selected from the group consisting of: lithium cobalt oxide, lithium manganese oxide, lithium nickel manganese cobalt oxide, lithium iron phosphate, lithium nickel cobalt aluminium oxide, lithium titanium oxide, lithium nickel oxide, lithium niobium oxide, lithium vanadium oxide.

The layer of cathode is optionally selected from the group consisting of: LiCoO₂, LiNiO₂, LiNbO₂, LiVO₂, LiMnO₂, LiMn₂O₄, Li₂MnO₃, LiFePO₄, LiNiCoAlO₂ and Li₄Ti₅O₁₂.

The layer of cathode that forms comprises a deposited material, the deposited material optionally being able to exist in a lower energy crystal structure and a higher energy crystal structure, the layer of cathode optionally comprising the deposited material in the higher energy crystal structure. The terms “higher energy crystal” structure and “high energy crystal structure” are used interchangeably throughout the specification. The terms “lower energy crystal structure” and “low energy crystal structure” are used interchangeably throughout the specification. The terms “lower” and “higher” are used to indicate the relative energies of the two crystal structures.

The higher energy crystal structure may be a crystal structure that would form from the application of an annealing process at an elevated temperature, optionally at a temperature of at least 400° C., to a bulk sample of a low energy crystal structure. For the avoidance of doubt, the deposited material preferably has substantially the same chemical composition in both the higher energy crystal structure and the lower energy crystal structure. For the avoidance of doubt, the bulk sample and layer of cathode optionally have the same chemical composition.

The method may therefore comprise a method of depositing a layer having a high energy crystal structure without annealing.

It may be the case that in the absence of a bias voltage on the substrate, the higher energy crystal structure is not formed, or is formed in a lower amount. The method may comprise reductions in the application of voltage bias (optionally to zero) to the substrate in order to allow the amount of higher energy crystal structure that forms to be controlled.

The layer of cathode that forms optionally comprises a higher energy crystal structure wherein the higher energy crystal structure is defined as the crystal structure that would form from the application of an annealing process at a temperature greater than 400° C. to a bulk sample of a lower energy crystal structure, wherein the higher energy crystal structure and the lower energy crystal structure optionally have substantially the same chemical formula, and the bulk sample optionally has substantially the same chemical formula as the layer of cathode.

A compound, or other chemical species, may have a number of different crystal structures, and/or phases, that it can exist in. A sample of a compound or chemical species may therefore take a different crystallographic form depending on the processing conditions in which it has been formed. A higher energy crystal structure is optionally a crystal structure that has a higher degree of order than a lower energy crystal structure. Forming a higher energy crystal structure requires energy input to a lower energy crystal structure. Direct measurements of the energy needed for some high energy crystal structures to form can sometimes be difficult to obtain. This is especially difficult in high energy crystal structures where the formation, at least in part, is limited by diffusion effects. An example of such a structure is the hexagonal form of LiCoO₂. An approximation of the energy required to form a high energy crystal structure is the annealing temperature that would need to be applied to a bulk sample of a low energy crystal structure (of the same chemical compound or species) in order to promote the phase change to the high energy crystal structure.

The term “a bulk sample” is well known to those skilled in the art. A bulk sample may be a sample that has no dimension less than 1 cm in length, and a volume no smaller than 1 cm³. Such a sample is considered to show bulk properties, and does exhibit properties that may arise in samples of the same species that have at least one dimension that is sufficiently small that at least property of the material differs substantially from the respective property of the bulk material.

The annealing process of the bulk sample would be what occurs under reference conditions. The pressure under these conditions would be atmospheric pressure.

The temperature of the annealing process of the bulk sample is optionally at least 400° C., optionally at least 500° C. and optionally 600° C. The temperature of the annealing process is optionally no more than 1400° C., optionally no more than 1000° C. and optionally no more than 800° C. The temperature of the annealing process may be from 400° C. to 1000° C., optionally from 500° C. to 800° C., and optionally from 600° C. to 700° C.

The higher energy crystal structure optionally comprises a rhombohedral or hexagonal crystal structure. If the higher energy crystal structure comprises a lithium-containing material, for example, LiCoO₂, the higher energy crystal structure of the LiCoO₂ that is deposited is optionally in the R3̅m space group.

The R3̅m space group structure is a layered oxide structure. This structure has a number of benefits, such as having a high usable capacity and high speed of charging and discharging compared to the low energy structure of LiCoO₂, which has a structure in the Fd3m space group. The R3̅m space group is regarded as having better performance in typical battery applications due to enhanced reversibility and fewer structural changes on lithium intercalation and de-intercalation. Therefore, crystalline LiCoO₂ in the R3̅m space group is favoured for solid-state battery applications

The layer of cathode that forms optionally comprises a volume fraction of the higher energy crystal structure, wherein the volume fraction of the higher energy crystal structure present in the layer of cathode is higher than the volume fraction of the lower energy crystal structure when the power density associated with the voltage bias of the substrate is above a critical value.

A critical value is a value at which a proportion of one crystal structure transforms into another crystal structure. Therefore, below the critical value there may be a relatively small amount of the higher energy crystal structure, and above that value, there may be a relatively large amount of the higher energy crystal structure. The critical value may be an average, or midpoint, of a range of values of voltage bias associated with the substrate. The range of values may correspond to a phase change region. For example, when deposition occurs within the range of values, the deposited layer of cathode may comprise a volume fraction that forms in the higher energy crystal structure and a volume fraction that forms in the lower energy crystal structure. The critical value may be the voltage bias associated with the substrate which forms a layer of cathode wherein substantially 50% of the volume of the layer of cathode is in the higher energy crystal structure, and substantially 50% of the volume of the layer of cathode is in the low energy crystal structure.

The volume fraction of the higher energy crystal structure present in the layer of cathode may only be higher than the volume of the low energy crystal structure where the power associated with the voltage bias of the substrate is less than the value at which material, optionally alkali metal ions such as lithium ions, present in the layer of cathode would begin to be re-sputtered.

The volume fraction of the higher energy crystal structure present in the layer of cathode is optionally positively correlated to the power density associated with the voltage bias of the substrate. Optionally, the positive correlation is a proportional correlation.

The volume fraction of the lower energy crystal structure is optionally substantially zero.

The volume fraction of the higher energy crystal structure is optionally no less than 80% and the volume fraction of the lower energy crystal structure is optionally no more than 20%. The volume fraction of the higher energy crystal structure is optionally no less than 90% and the volume fraction of the lower energy crystal structure is optionally no more than 10%. The volume fraction of the higher energy crystal structure is optionally substantially 100% and the volume fraction of the lower energy crystal structure is optionally 0%.

The critical value of the power density associated with the voltage bias of the substrate is optionally at least 1 Wcm⁻² and optionally at least 1.8 Wcm⁻². The critical value of the power density associated with the voltage bias of the substrate is optionally no more than 4.0 Wcm⁻², optionally no more than 3.0 Wcm⁻² and optionally no more than 2.8 Wcm⁻². The critical value of the power density associated with the voltage bias of the substrate may be from 1.0 Wcm⁻² to 4.0 Wcm⁻², optionally from 1.5 Wcm⁻² to 3.8 Wcm⁻², and optionally from 1.8 Wcm⁻² to 3.4 Wcm⁻².

The critical value preferably corresponds to a power associated with a voltage bias on the substrate of at least 200 W, and optionally at least 350 W. The critical value preferably corresponds to a voltage bias on the substrate which draws a power no more than 700 W, optionally no more than 550 W and optionally no more than 450 W. The critical value preferably corresponds to a voltage bias on the substrate that draws a power from 200 W to 700 W, optionally from 300 W to 550 W, and optionally from 350 W to 450 W.

The higher energy crystal structure optionally has a characteristic first X-ray diffraction pattern, and the lower energy crystal structure optionally has a characteristic second X-ray diffraction pattern, wherein the first X-ray diffraction pattern optionally comprises a first characteristic peak indicative of the presence of the higher energy crystal structure and the second X-ray diffraction pattern optionally comprises a second characteristic peak indicative of the presence of the lower energy crystal structure.

Optionally, the area under the first characteristic peak is higher than the area under the second characteristic peak when the power density associated with the voltage bias of the substrate is above a critical value. The area under a characteristic peak would be understood by the skilled person to mean the integral of the function that defines the pattern of the characteristic peak, or an approximation of said integral.

Those skilled in the art will recognise that the higher the area under the first characteristic peak, the greater the volume fraction of the higher energy crystal structure in the layer of cathode.

Those skilled in the art will recognise that the lower the area under the second characteristic peak, the lower the volume fraction of the lower energy crystal structure in the layer of cathode.

The first diffraction pattern is optionally that of a hexagonal or rhombohedral structure. The first diffraction pattern is optionally that of a material in the R3̅m space group. The first characteristic peak is optionally that of the (101), (110) or (003) plane, and preferably the (003) plane. The second diffraction pattern is optionally that of a cubic crystal structure. The second diffraction pattern is optionally that of a material in the Fd3m space group. The second characteristic peak is optionally that of the (111) plane.

Optionally, the degree of crystallinity of the layer of cathode is positively proportional to the power density associated with the voltage bias applied to the substrate.

The degree of crystallinity of the layer of cathode may be (optionally directly) proportional to the power density associated with the voltage bias of the substrate only where the power associated with the voltage bias of the substrate is less than the value at which material, optionally alkali metal ions such as lithium ions present in the layer of cathode, would begin to be re-sputtered.

Crystallinity refers to the degree of structural order in a solid. In a crystal, the atoms or molecules are arranged in a regular, periodic manner A material with a higher degree of crystallinity with maintain a regular, periodic order over a larger distance than a material with a lower degree of crystallinity.

As the degree of crystallinity increases, a number of different parameters of the material change. A material with an improved crystallinity may have a larger crystallite size. A material with an improved crystallinity may have an improved texture, such that the crystallographic orientations of the crystallites in the material are more narrowly distributed. A material with an improved crystallinity may have fewer dislocations and stacking faults. A material with an improved crystallinity may have and lower stress-strain accumulation in the material.

The layer of cathode that forms optionally has a characteristic X-ray diffraction pattern, wherein the X-ray diffraction pattern optionally comprises at least one peak, the at least one peak having a Full Width at Half Maximum value, wherein the Full Width at Half Maximum value of the at least one peak is optionally negatively proportional to the power density associated with the voltage bias of the substrate.

The Full Width at Half Maximum value may be negatively proportional to the power density associated with the voltage bias of the substrate only when the power associated with the voltage bias of the substrate is less than the value at which material, optionally alkali metal ions such as lithium ions, present in the layer of cathode would begin to be re-sputtered.

In X-ray crystallography, the Full Width at Half Maximum (FWHM) is a measure that can be calculated with respect to a peak in an X-ray diffraction pattern. The Full Width at Half Maximum is the width of a spectrum curve measured between those points on the y-axis (i.e. intensity) which are half the maximum amplitude of the peak being considered.

Full Width at Half Maximum is a measure that holistically gives an indication of the features that relate to crystallinity. In general, a smaller value of Full Width at Half Maximum for a crystallographic peak relating to a particular reflection in one sample of material, compared to the Full Width at Half Maximum for a crystallographic peak relating to the same reflection in another sample of material, indicates an increase in crystallinity. Therefore, a smaller Full Width at Half Maximum value indicates at least some of the following changes in material properties: smaller crystallite size, improved texture, fewer dislocations and stacking faults, and/or lower stress-strain accumulation in the material.

When an X-ray diffraction pattern is obtained, the Full Width at Half Maximum measured directly from the peaks of the diffraction pattern may be considered absolute Full Width at Half Maximum values. An absolute Full Width at Half Maximum value comprises an instrument component that is derived from the specific characterisation parameters used during the collection of the X-ray diffraction pattern, and a sample component that is derived from the material properties of the sample being measured. The sample component of the absolute Full Width at Half Maximum value can be called the normalised Full Width at Half Maximum.

The Full Width at Half Maximum value may be a normalised Full Width at Half Maximum value.

Parameters which may affect the instrument component of the absolute Full Width at Half Maximum value may comprise the radiation source used in the X-ray spectrometer, the temperature during spectra collection, and the range of angles through which the spectra is collected.

Parameters which may affect the sample component of the absolute Full Width at Half Maximum value may comprise any variables of the sputter deposition process that may affect the crystallinity of the deposited sample. These include: the specific materials being deposited; the type and number of targets being used; the thicknesses of layers being deposited, and the thickness of layers that may have previously been deposited; the thickness and material of the substrates on to which material is being deposited, the power applied to the plasma source, the power applied to the targets, the process pressure of a deposition chamber in which the process is being carried out, and the presence of any reactive gases in the sputtering process.

The Full Width at Half Maximum value may be a normalised Full Width at Half Maximum value, which comprises the sample component of the absolute Full Width at Half Maximum value de-convoluted from the absolute Full Width at Half Maximum value, such that the normalised Full Width at Half Maximum value is independent of the instrument component of the absolute Full Width at Half Maximum.

The absolute Full Width at Half Maximum value is optionally no more than 2 degrees, optionally at least 0.2 degrees and optionally at least 0.1 degrees. The absolute Full Width at Half Maximum is optionally greater than 0.01 degrees, optionally greater than 0.05 degrees and optionally greater than 0.09 degrees. The absolute Full Width at Half Maximum value may be from 0.01 to 1 degrees, optionally from 0.05 to 0.5 degrees, and optionally from 0.09 to 0.1 degrees. It has unexpectedly been found that applying a bias voltage results in decreasing the Full Width at Half Maximum values (absolute or normalised) of the one or more peaks of any X-ray diffraction pattern collected from a deposited cathode layer.

A rationalised Full Width at Half Maximum value may be calculated by setting the Full Width at Half Maximum value to 1 for a sample deposited with a minimum acceptable voltage bias applied to the substrate (which may, for example, be 200 W), and measuring the percentage change in Full Width at Half maximum relative to this value. The rationalised Full Width at Half Maximum value is optionally less than 1, optionally at least less than 0.92 and optionally 0.88. The rationalised Full Width at Half Maximum value is optionally greater than 0.8, optionally greater than 0.85 and optionally greater than 0.87. The rationalised Full Width at Half Maximum may be from 0.8 to 1, optionally from 0.85 to 0.95, and optionally 0.88.

A bias may be applied to the target during the sputtering material from the target or targets using the plasma. This bias on the target has a power associated with it.

The ratio of the power used to generate the plasma to a power associated with a bias on the target or targets is optionally greater than 1:1

The ratio of the power used to generate the plasma to the power associated with the bias on the target may be greater than or equal to 1:1, optionally less than or equal to 7:2 and is optionally less than or equal to 3:2. The applicant has discovered that such power ratios may be beneficial in depositing crystalline materials without the need to anneal the material so deposited.

The actual power in the plasma may be less than the power used to generate the plasma. In this connection, the efficiency of the generation of the plasma ([actual power in the plasma/power used to generate the plasma]×100) may typically be from 50% to 85%, typically about 50%.

During steady-state performance of the method (in which electrical energy supplied to the system is, within a margin of error, the same as the energy consumed by the system), it may be that the fraction of (PP*EPT)/(PT*EPP) is greater than 1, optionally in the range of 1 to 4, possibly in the range of 1 to 3, and in certain embodiments between 1 and 2, wherein PP=the average use of plasma energy (in Watts), PT=the power associated with the bias on the target, EPP is a fraction (<1) being a measure of the efficiency of plasma generation and EPT is a fraction (<1) being a measure of the efficiency of the supply of electrical energy to the target(s). The efficiency, EPP, of the generation of the plasma may be calculated as [actual power in the plasma]/[electrical power used to generate the plasma.

The efficiency, EPT, of the supply of electrical energy to the target may be calculated as [actual power delivered]/[electrical power used]. In typical set-ups it may be assumed that EPT=1. It is preferred that EPT>0.9.

During steady-state performance of the method, it may be that the normalised power ratio parameter, PRPN (where NPRPN=N*PP/PT and where N is a normalising factor, which may satisfy 1.2<N<2, or may simply be N=1.7) is greater than 1, optionally in the range of 1 to 4, possibly in the range of 1 to 3, and in certain embodiments between 1 and 2. During steady-state performance of the method, it may be that the power ratio parameter, PRP (where PRP=PP/PT) is greater than 0.5, optionally in the range of 0.5 to 2, possibly in the range of 0.6 to 1.5, and in certain embodiments between 0.6 and 1.

The material sputtered from the target optionally passes through the remotely generated plasma before depositing on the substrate.

The remotely generated plasma may be of high energy.

The remotely generated plasma may be of high density. In this connection, the plasma may have an ion density of at least 1011 cm 3.

The power density associated with the voltage bias of the target is optionally greater than 1 Wcm⁻² and optionally up to 100 Wcm⁻².

The substrate may comprise a flexible substrate. The method of the present invention may advantageously be used with flexible substrates, such as substrates that comprise one or more polymers, such as PET or PEN.

The substrate may have a thickness of no more than 50 μm, optionally no more than 20 μm, optionally no more than 10 μm, optionally no more than 5 μm and optionally no more than 1.6 μm. The use of annealing typically exposes the substrate to relatively high temperatures. This can cause thermal damage to the substrate and/or may make the substrate difficult to handle. It is therefore beneficial to be able to deposit crystalline material onto thin substrates without the need to expose the substrate to annealing temperatures.

The substrate may comprise a polymer, such as an organic polymer, for example, polyethylene terephthalate (PET), polyimide (PI) or polyethylene naphthalate (PEN). The polymer may optionally provide support for the substrate.

The substrate may optionally be optimised for use in roll-to-roll processing.

The temperature of the substrate during the deposition of the layer of cathode is optionally no more than 500° C., optionally no more than 300° C., optionally no more than 200° C., optionally no more than 150° C., optionally no more than 120° C. and optionally no more than 100° C. The method of the present invention may take place at a low temperature, which facilitates the use of substrates and other materials which may not be usable at high temperatures. Furthermore, the handling of substrates at higher temperatures may be more difficult.

The maximum temperature reached at any given time by any given square of substrate material having an area of 1 cm² as measured on the surface opposite to said surface on which the material is deposited and as averaged over a period of 1 second, may be no more than 500° C., optionally no more than 300° C., optionally no more than 200° C., optionally no more than 150° C., optionally no more than 120° C. and optionally no more than 100° C.

The method may comprises providing first and second targets. The target material of the first and second targets may optionally be different. The orientation of the first and second targets relative to the substrate may be mutually different.

The method may comprise exposing the first target to the plasma, and exposing the second target to the plasma, thereby sputtering material from the first and second targets. The substrate may be exposed to material sputtered from the first and second targets. The sputtering of material from the first target may generate a first plume corresponding to the trajectories of particles from the first target assembly onto the substrate. The sputtering of material from the second target may generate a second plume corresponding to the trajectories of particles from the second target assembly onto the substrate. The first and second plumes may converge at the substrate, thereby forming the layer of cathode. The first and second targets may be configured such that more plasma energy may be received at one of the first and second targets than at the other of the first and second targets. This may be beneficial if the energy required to sputter the material of the first or second target is greater than the energy requires to sputter the material of the other of the first or second target. For example, if the first target comprises elemental lithium and the second target comprises cobalt, then the first and second targets may be configured such that the second target received more plasma energy than the first target because cobalt requires more energy than lithium to sputter from the target.

The working distance between the target and the substrate may be within +/−50% of the theoretical mean free path of the system.

Without wishing to be bound by theory, it is believed that the working distance also has an influence on the ad atom energy of the sputtered material as it deposits onto the substrate. In a case where the working distance is greater than the mean free path of the system, it is thought that it is more likely that an ion in the sputter flux would be involved in a collision before reaching the substrate, resulting in relatively low ad atom energy. Conversely, if the working distance is shorter than the mean free path of the system, the ad atom energy is relatively high.

A definition of the mean free path is the average distance between collisions for an ion in the plasma. The mean free path is calculated based on the volume of interaction (varied by the working distance), and the number of molecules per unit volume (varied by the working pressure).

The working distance is optionally at least 3.0 cm, optionally at least 4.0 cm and optionally 5.0 cm. The working distance is optionally no more than 20 cm, optionally no more than 15 cm and optionally no more than 13 cm. The working distance may be from 4.0 cm to 13 cm, optionally from 6.0 cm to 10 cm, and optionally from 8.0 cm to 9.0 cm.

Optionally, the process occurs inside a deposition chamber, and a working pressure is defined as the chamber pressure prior to the igniting of the remote plasma, said working pressure being at a substantially constant value throughout the deposition process, said value optionally being between 0.00065 mBar and 1e-2 mBar.

The working pressure is optionally at least 0.0005 mBar, optionally at least 0.00065 mBar, optionally at least 0.0010 mBar, optionally at least 0.0020 mBar, optionally at least 0.0030 mBar, optionally at least 0.0040 mBar, and optionally at least 0.0045 mBar. The working pressure is optionally no more than 0.0100 mBar, optionally no more than 0.0090 mBar, optionally no more than 0.0080 mBar, optionally no more than 0.0070 mBar, and optionally no more than 0.0065 mBar. The working pressure is optionally from 0.0005 mBar to 0.0100 mBar, optionally from 0.0020 mBar to 0.0090 mBar, optionally from 0.0030 mBar to 0.0080 mBar, optionally from 0.0040 mBar to 0.0070 mBar, and optionally from 0.0045 mBar to 0.0065 mBar.

The working pressure may be from 0.00065 mBar to 0.01 mBar, optionally from 0.001 to 0.007 mBar. A higher working pressure in this range may result in a higher deposition rate. This is because a higher working pressure results in a larger number of process ion (usually Ar+) bombardments on the surface of the target, and hence material is sputtered from the target at a higher rate.

When the working distance is from 8.0 to 9.0 cm, the range of crystallite sizes available may be narrower, for example, if a working pressure of from 0.001 mBar to 0.0065 mBar is used.

The flow rate may be from 5 sccm to 200 sccm, optionally from 50 sccm to 150 sccm. A higher working pressure in this range may result in a higher deposition rate. This is because a higher working pressure results in a larger number of process ion (usually Art) bombardments on the surface of the target, and hence material is sputtered from the target at a higher rate.

The deposition may occur in a reactive atmosphere. A reactive atmosphere comprises ions of the sputter gas, and ions of at least one reactive gas. The reactive gas may comprise oxygen and/or nitrogen.

In accordance with a second aspect of the invention, there is provided a method of forming a layer of cathode optionally for a solid-state battery on a substrate, the layer of cathode comprising deposited material, the deposited material being capable of existing in a lower energy crystal structure and a higher energy crystal structure, the method comprising:
generating a plasma remote from one or more sputter targets,
sputtering material from the target or targets using the plasma, and depositing the sputtered material on the substrate to which a bias voltage has been applied, thereby forming the layer of cathode, the layer of cathode comprising deposited material in the higher energy crystal structure.

As previously stated, these higher energy crystal structures may be formed on a substrate by depositing the material with the lower energy crystal structure using plasma deposition techniques, and then annealing to form the higher energy crystal structure which is used as a cathode material. As indicated above in relation to the method of the first aspect of the present invention, the annealing process typically involves heating the lithium-containing material to temperatures of about 400° C., in in the case of some high energy crystal structures, 600° C. This requires a lot of energy and exposes any other materials associated with the high energy crystal structure, such as underlying substrates, to such temperatures which may not be desirable.

The method of the second aspect of the present invention may comprise any of the features described above in relation to the method of the first aspect of the present invention. For example, the substrate, the deposited material, the lower energy crystal structure and the higher energy crystal structure may have the features described above in relation to the method of the first aspect of the present invention. As mentioned above in relation to the method of the first aspect of the present invention, the bias voltage may be applied to a support on which the substrate rests.

In accordance with a third aspect of the present invention, there is provided a method of forming a solid state battery half-cell, the method comprising:
forming a layer of cathode in accordance with the method of the first or second aspect of the present invention wherein the layer of cathode is a cathode layer; and
depositing an electrolyte material suitable for a solid state battery cell on the cathode layer.

The electrolyte is optionally a ceramic material, such as LiPON (lithium phosphorous oxynitride). The method may comprise generating a plasma remote from one or more targets comprising target material (such as Li₃PO₄); exposing the plasma target or targets to the plasma, thereby sputtering material from the target or targets, optionally in a reactive atmosphere comprising a reactive gas (such as nitrogen), thereby forming ceramic material (such as LiPON) on the battery cathode.

Alternatively, the electrolyte comprises a polymer. In this case, the method may comprise depositing a polymer onto said battery cathode. Alternatively or additionally, the method may comprise depositing a precursor onto said battery cathode and forming a polymer from the precursor.

The method may comprise depositing a current collecting layer on the ceramic battery electrolyte material.

In accordance with a fourth aspect of the present invention, there is provided a method of forming a solid state battery cell, the method comprising:
forming a solid state battery half-cell in accordance with the third aspect of the present invention; and
contacting anode material suitable for a solid state battery cell on the electrolyte material.

The anode-forming material may comprise an electrically-conductive material. The anode-forming material may comprise a lithium alloy or a metal, such as lithium or copper.

In accordance with a fifth aspect of the present invention, there is provided a method of forming a solid-state battery, the method comprising repeatedly:
forming a layer of cathode of a solid-state battery, wherein said layer of cathode is a cathode;
depositing electrolyte material on the layer of cathode; and
depositing anode material on the electrolyte material;
wherein at least one step of forming a layer of cathode of a solid-state battery comprises a method in accordance with the first or second aspect of the present invention.

In accordance with a sixth aspect of the present invention, there is provided a substrate provided with a layer made in accordance with the method of the first or second aspect of the present invention.

In accordance with a seventh aspect of the present invention, there is provided a substrate provided with a layer of cathode of a solid-state thin film device, the layer of cathode being made in accordance with the method of the first or second aspect of the present invention, wherein the layer of cathode is a cathode of a solid state battery.

In accordance with a eighth aspect of the present invention, there is provided a solid-state battery half-cell made in accordance with a method of the third aspect of the present invention.

In accordance with an ninth aspect of the present invention, there is provided a solid-state battery cell made in accordance with a method of the fourth aspect of the present invention.

In accordance with a tenth aspect of the present invention, there is provided a solid-state battery made in accordance with a method of the fifth aspect of the present invention.

In accordance with an eleventh aspect of the present invention, there is provided a method of forming a crystalline layer of cathode, optionally for a solid-state battery, on a substrate, the method comprising:
generating a plasma remote from one or more sputter targets,
sputtering material from the target or targets using the plasma, and
depositing the sputtered material on the substrate to which a bias voltage has been applied, thereby forming the crystalline layer, the power density associated with the bias voltage having been determined to provide the crystalline layer of a desired crystallinity.

The relationship between the power density and desired crystallinity may be an established, known pre-determined relationship, and therefore determining the power density may merely comprise selecting a power density based on a pre-determined, known relationship between the power density and crystallinity.

The relationship between the power density and the desired crystallinity may not be known, however. The method may therefore comprise depositing a first crystalline layer using a bias voltage associated with a first power density and determining the crystallinity of the first crystalline layer, and depositing a second crystalline layer using a bias voltage associated with a second power density and determining the crystallinity of the second crystalline layer, the second power density being different from the first power density, and based on the crystallinity of the first and second crystalline layers, determining a power density to provide a crystalline layer of the desired crystallinity. In this case, the method would optionally comprise;

generating a plasma remote from one or more sputter targets,
sputtering material from the target or targets using the plasma, and
depositing the sputtered material on a first portion of substrate to which a bias voltage has been applied, thereby forming a first crystalline layer, the first power density associated with the bias voltage producing the crystalline layer having a first crystallinity; and
generating a plasma remote from one or more sputter targets,
sputtering material from the target or targets using the plasma, and
depositing the sputtered material on a second portion of substrate to which a bias voltage has been applied, thereby forming a second crystalline layer, the second power density associated with the bias producing the second crystalline layer having a second crystallinity, and
based on the crystallinity of the first and second crystalline layers, determining a power density to provide a crystalline layer of the desired crystallinity.

Crystallinity may be measured using the FWHM of one or more X-ray diffraction peaks, optionally normalised by de-convoluting any contribution from the X-ray diffraction apparatus (such as may result from finite beam width, detector imperfections etc.).

In accordance with a twelfth aspect of the present invention, there is provided method of determining a function which describes the crystallinity of a layer of cathode of material as a result of a change in voltage bias applied to a substrate during the deposition of said cathode material, comprising;
generating a plasma remote from one or more sputter targets,
sputtering material from the target or targets using the plasma, and
depositing the sputtered material on a first portion of substrate to which a bias voltage has been applied, thereby forming a first crystalline layer, the first power density associated with the bias voltage producing the crystalline layer having a first crystallinity; and
generating a plasma remote from one or more sputter targets,
sputtering material from the target or targets using the plasma, and
depositing the sputtered material on a second portion of substrate to which a bias voltage has been applied, thereby forming a second crystalline layer, the second power density associated with the bias producing the second crystalline layer having a second crystallinity, and
based on the crystallinity of the first and second crystalline layers, determining a function which describes the relationship between the power density associated with the bias on the substrate and the crystallinity of the layer of cathode.

The Full Width at Half Maximum values can be either an absolute Full Width at Half Maximum value or a normalised Full Width at Half Maximum value. The definitions of the absolute and normalised Full Width at Half Maximum values in this aspect of the invention are the same as those described in previous aspects of the invention.

Optionally, the function takes the form of a linear regression function.

The function may be used to predict the degree of crystallinity for a proposed value of voltage bias, or value of power density associated with the voltage bias on the substrate. The function may be used to predict a Full Width at Half Maximum value for a proposed value of voltage bias, or value of power density associated with the voltage bias on the substrate.

The function may be used to predict the value of voltage bias, or value of power density associated with the voltage bias on the substrate, required in order to form a layer of cathode with a desired degree of crystallinity. The function may be used to predict the value of voltage bias, or value of power density associated with the voltage bias on the substrate required in order to form a layer of cathode that exhibits a desired Full Width at Half Maximum value.

For the avoidance of doubt, the methods of the eleventh and twelfth aspects of the present invention may comprise any of the features described above in relation to the method of the first aspect of the present invention. For example, the substrate, the deposited material, the lower energy crystal structure and the higher energy crystal structure may have the features described above in relation to the method of the first aspect of the present invention. As mentioned above in relation to the method of the first aspect of the present invention, the bias voltage may be applied to a support on which the substrate rests.

In accordance with a thirteenth aspect of the present invention, there is provided a method of forming a layer of cathode according to the first aspect or second aspect of the invention, further including the steps of;
selecting a desired degree of crystallinity,
using the method of the twelfth aspect of the invention to determine a voltage bias to be applied to the substrate such that the material forms with the desired crystallinity.

In accordance with a fourteenth aspect of the present invention, there is provided a method of forming a crystalline layer of cathode optionally for a solid-state battery on a substrate, the crystalline layer comprising a deposited material, the deposited material being capable of existing in a lower energy crystal structure and a higher energy crystal structure, the method comprising:
generating a plasma remote from one or more sputter targets,
sputtering material from the target or targets using the plasma, and
depositing the sputtered material on the substrate to which a bias voltage has been applied, thereby forming the crystalline layer, the power density associated with the bias voltage having been determined to provide the desired lower energy or higher energy crystal structure.

The method may therefore comprise selecting the lower energy or higher energy crystal structure and based on said selection, determining the power density associated with the bias voltage required to provide the selected lower energy or higher energy crystal structure.

The layer of cathode may optionally comprise substantially all of its volume being the low energy crystal structure. The crystalline layer of cathode may optionally comprise substantially all of its volume being the high energy crystal structure. The layer of cathode may optionally have part of its volume comprising the high energy crystal structure and part of its volume comprising the low energy crystal structure, wherein the volume of the high energy crystal structure is larger than the volume of the low energy crystal structure.

The relationship between the power density and the crystal structure formed may be an established, known pre-determined relationship, and therefore determining the power density may merely comprise selecting a power density based on a pre-determined, known relationship between the power density and crystal structure.

The relationship between the power density and the crystal structure may not be known, however.

The method may therefore comprise depositing a first crystalline layer using a bias voltage associated with a first power density and determining the crystal structure of the first crystalline layer, and depositing a second crystalline layer using a bias voltage associated with a second power density and determining the crystal structure of the second crystalline layer, the second power density being different from the first power density, and based on the crystal structures of the first and second crystalline layers, determining a power density to provide a crystalline layer of the desired lower energy or higher energy crystal structure. In this case, the method would optionally comprise
generating a plasma remote from one or more sputter targets,
sputtering material from the target or targets using the plasma, and
depositing the sputtered material on a first portion of substrate to which a bias voltage has been applied, thereby forming a first crystalline layer, and determining the crystal structure of the first crystalline layer; and
generating a plasma remote from one or more sputter targets,
sputtering material from the target or targets using the plasma, and
depositing the sputtered material on a second portion of substrate to which a bias voltage has been applied, thereby forming a second crystalline layer, and determining the structure of the second crystalline layer.
and based on the structures of the first and second crystalline layers, determining a power density to provide the desired lower or higher energy crystal structure.

Optionally, the ratio of the area under the first characteristic peak and the area under the second characteristic peak for the layer of cathode of material directly indicated the volume fraction of the high energy crystal structure in the layer of cathode. For example, the ratio being 3:1 indicates that 75% of the layer of cathode, by volume, is the high energy crystal structure.

In accordance with a fifteenth aspect of the present invention, there is provided a method of determining a function which describes the phase distribution of a layer of cathode of material, which comprises a volume fraction of a high energy crystal structure and a volume fraction of a low energy crystal structure, as a result of a change in voltage bias applied to a substrate during the deposition of said cathode material, comprising;
generating a plasma remote from one or more sputter targets,
sputtering material from the target or targets using the plasma, and depositing the sputtered material on a first portion of substrate to which a bias voltage has been applied, thereby forming a first crystalline layer, and determining the crystal structure of the first crystalline layer; and
generating a plasma remote from one or more sputter targets,
sputtering material from the target or targets using the plasma, and depositing the sputtered material on a second portion of substrate to which a bias voltage has been applied, thereby forming a second crystalline layer, and determining the structure of the second crystalline layer and,
based on the structures of the first and second crystalline layers, determining a function which describes the relationship between the power density associated with the bias on the substrate and the volume fraction of the high energy crystal structure in the cathode layer.

The function may be used to predict if the high energy crystal structure will form for a proposed value of voltage bias, or value of power density associated with the voltage bias on the substrate. The function may be used to predict volume fraction of the high energy crystal structure that will form for a proposed value of voltage bias, or value of power density associated with the voltage bias on the substrate.

The function may be used to predict the value of voltage bias, or value of power density associated with the voltage bias on the substrate required in order to form the high energy crystal structure. The function may be used to predict the value of voltage bias, or value of power density associated with the voltage bias on the substrate required in order to form a desired volume fraction of the high energy crystal structure.

The ratio of the area under the first characteristic peak and the area under the second characteristic peak is optionally positively correlated to the volume fraction of the high-energy crystal structure in the layer of cathode, wherein the volume fraction of the high energy crystal structure present in the layer of cathode is higher than the volume fraction of the low energy crystal structure when the voltage bias on the substrate is above a critical value, and the method further comprises, initially:
selecting a desired volume fraction of high energy crystal structure,
if the desired volume fraction of the high energy crystal structure is higher than half (i.e. higher than 50%), selecting a voltage bias higher than the critical value, and if the desired volume fraction of the high energy crystal structure is lower than half (i.e. lower than 50%), selecting a voltage bias lower than the critical value.

For the avoidance of doubt, the method of the fourteenth and fifteenth aspects of the present invention may comprise any of the features described above in relation to the method of the first aspect of the present invention. For example, the substrate, the deposited material, the lower energy crystal structure and the higher energy crystal structure may have the features described above in relation to the method of the first aspect of the present invention. As mentioned above in relation to the method of the first aspect of the present invention, the bias voltage may be applied to a support on which the substrate rests.

In accordance with a sixteenth aspect of the present invention, there is provided a method of forming a layer of cathode according to the first or second aspect of the invention, further including the steps of;
selecting a desired volume fraction of high energy crystal structure to be present in the layer of cathode,
using the method of the fifteenth aspect of the invention to determine a voltage bias to be applied to the substrate such that the material forms with the desired volume fraction of high energy crystal structure.

In accordance with a seventeenth aspect of the present invention there is provided a method of determining the voltage bias at which a higher energy crystal structure would be present in a layer of cathode of material, wherein the method comprises repeatedly performing steps (1), (2) and (3) until a voltage bias is found that results in the formation of the higher energy crystal structure, wherein:
Step 1 comprises forming a layer of cathode according to the first aspect of the invention,
Step 2 comprises performing X-ray diffraction on the layer of cathode, to determine if the high energy crystal structure is present, and
Step 3 comprises adjusting the voltage bias to be applied to the substrate before returning to step 1.

It will of course be appreciated that features described in relation to one aspect of the present invention may be incorporated into other aspects of the present invention. For example, the method of the invention may incorporate any of the features described with reference any other method of the invention and vice versa.

### DETAILED DESCRIPTION

Embodiments of the present invention will now be described by way of example only with reference to the accompanying schematic drawings which can be briefly summarised as follows.

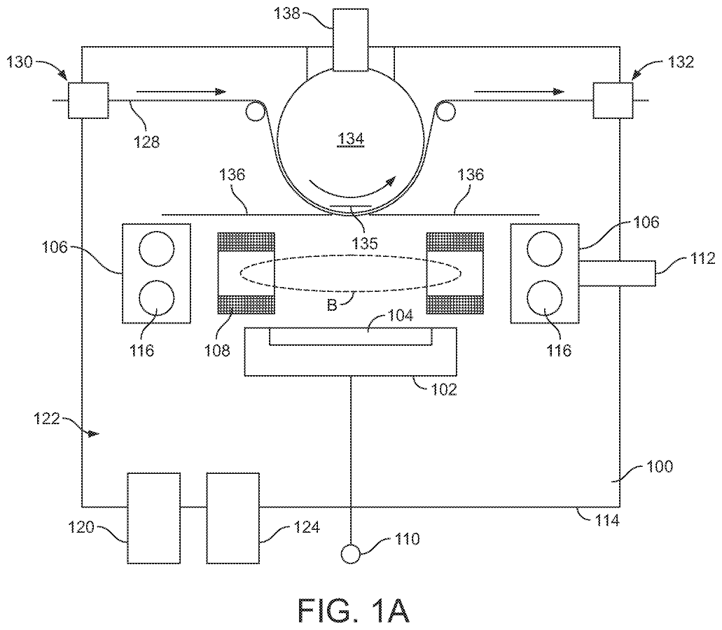

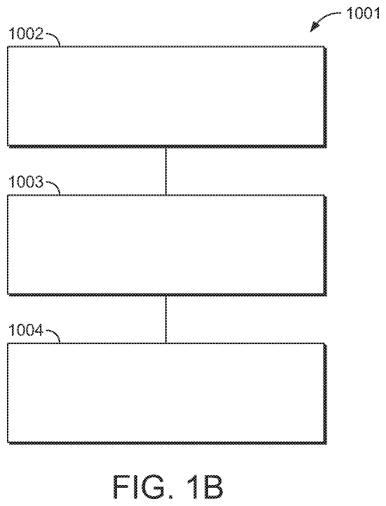

FIG. 1a is a schematic side-on view of a plasma deposition chamber used in accordance with a first example of the first aspect of the invention;

FIG. 1b shows the steps of a method of manufacturing a battery cathode in accordance with the first example of the first aspect of the invention;

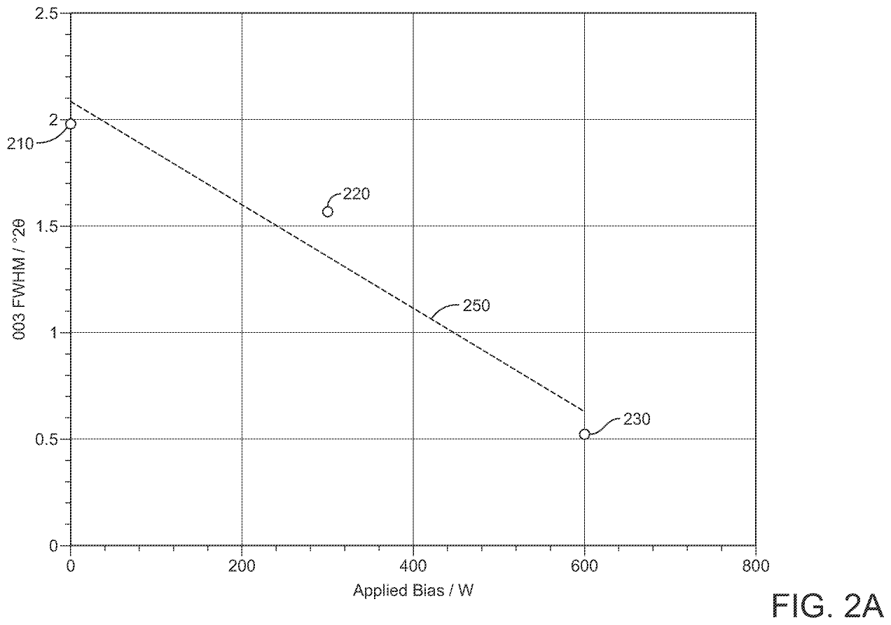

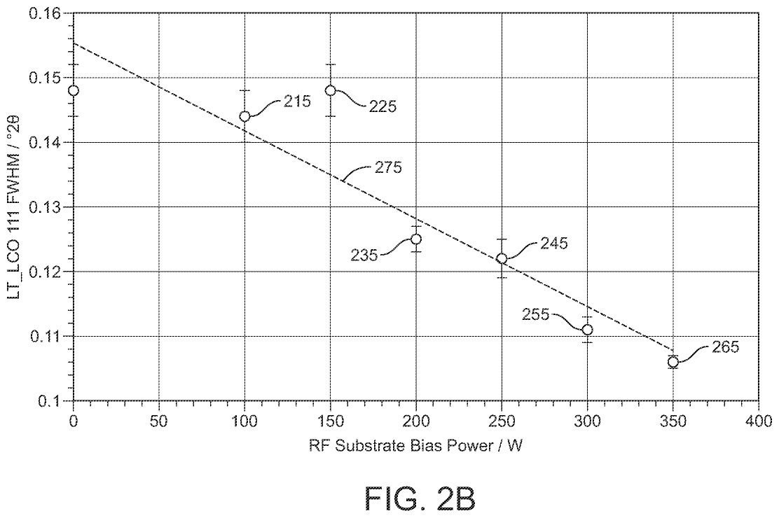

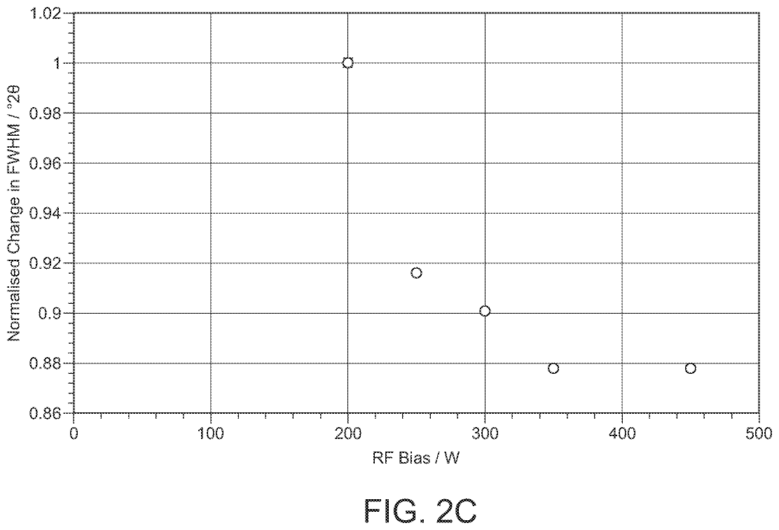

FIG. 2a shows X-ray diffraction Full Width at Half Maximum (FWHM) values of layers deposited in accordance with several examples of the present invention, plotted against the electrical power applied to the substrate;

FIG. 2b shows the Full Width at Half maximum values for several layers of cathode deposited using examples of methods of the first aspect of the present invention at different electrical powers applied to the substrate;

FIG. 2c shows a plot of the normalised Full Width at Half Maximum values obtained from layers of cathode deposited using examples of the method of the first aspect of the invention;

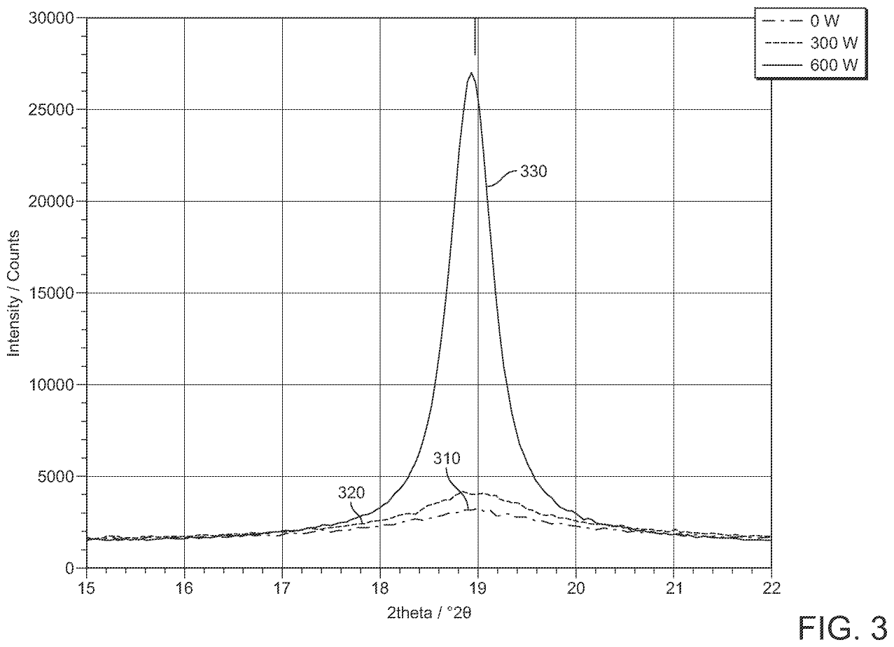

FIG. 3 shows the X-ray diffractions peaks of the (003) reflection of LiCoO₂ from which the FWHM values shown in FIG. 2a are derived;

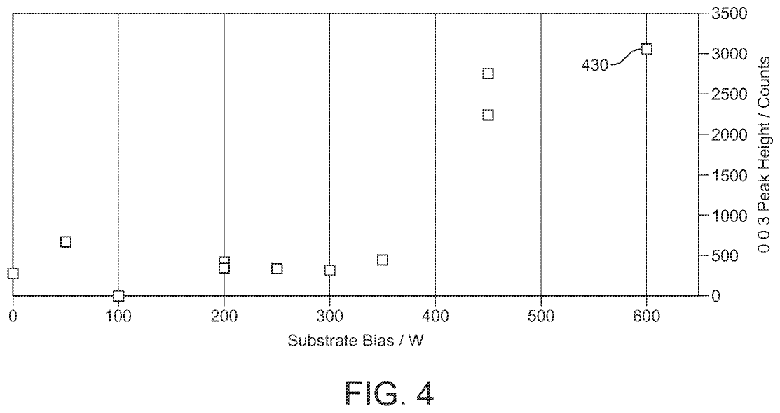

FIG. 4 shows the intensity of the (003) reflection of LiCoO₂ as a function of the power applied to the substrate;

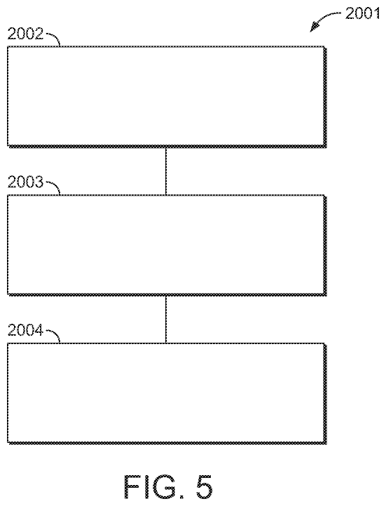

FIG. 5 is schematic representation of an example of a method of forming a layer of cathode optionally for a solid-state battery on a substrate in accordance with a first example of the second aspect of the invention;

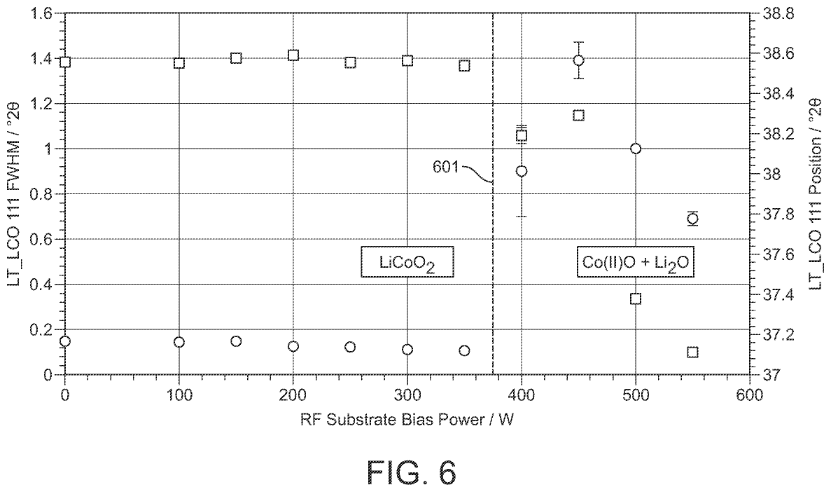

FIG. 6 shows the position and FWHM of the 111 peak obtained from LiCoO₂ deposited in accordance with examples of a method of the present invention, as a function of the power applied to the substrate;

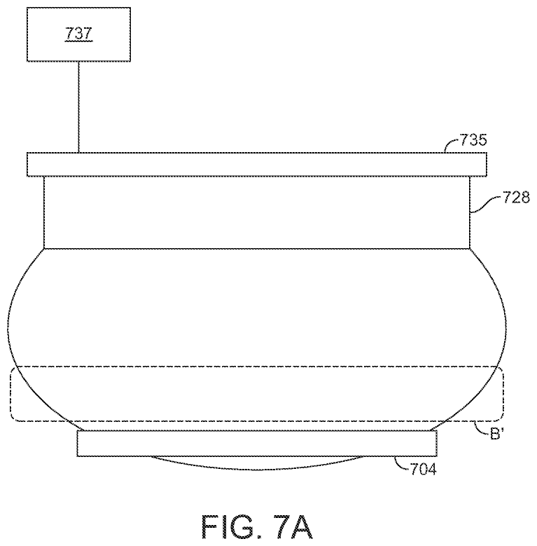

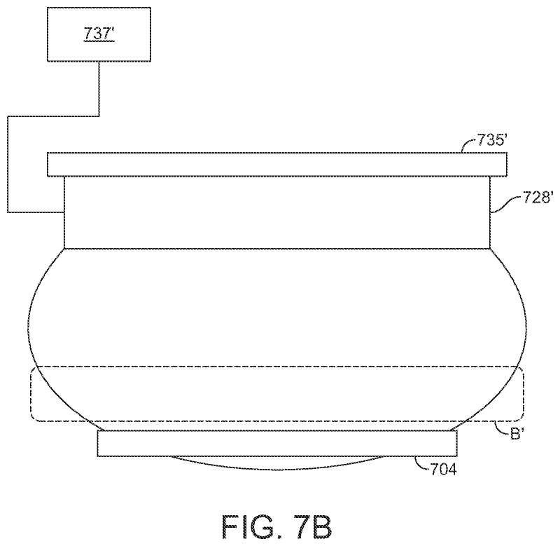

FIG. 7a shows a schematic representation of an apparatus used in a second example method of the first aspect of the invention;

FIG. 7b shows a schematic representation of an apparatus used in a third example method of the first aspect of the invention;

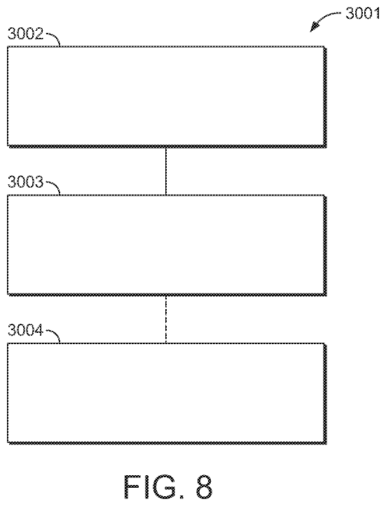

FIG. 8 is a schematic representation of an example of a method of forming a solid state battery half-cell in accordance with a first example of a third aspect of the invention;

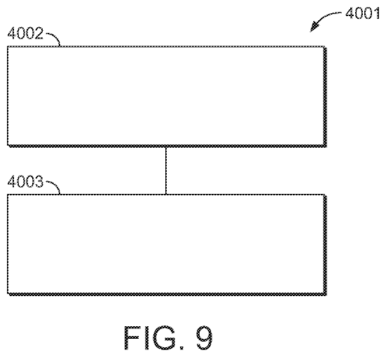

FIG. 9 is a schematic representation of an example of a method of forming a solid state battery cell in accordance with a fourth aspect of the invention;

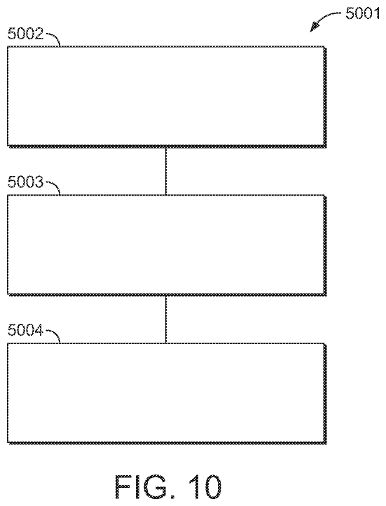

FIG. 10 is a schematic representation of an example of a method of making a solid-state battery in accordance with a fifth aspect of the invention;

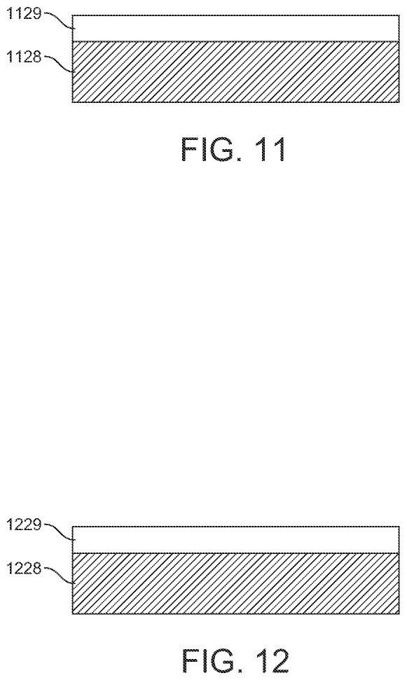

FIG. 11 shows a schematic representation of an example of a substrate in accordance with a sixth aspect of the present invention;

FIG. 12 is a schematic representation of an example of a substrate provided with a layer of cathode of a solid-state thin film device in accordance with a seventh aspect of the present invention;

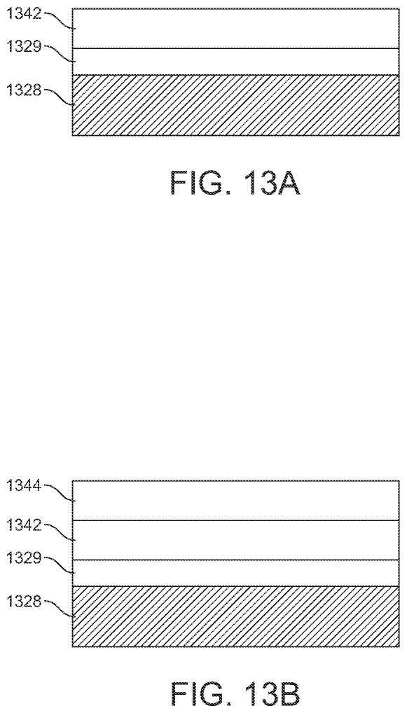

FIG. 13a is a schematic representation of an example of a solid-state battery half-cell according to an eighth aspect of the invention so made according to an example of the third aspect of the invention;

FIG. 13b is a schematic representation of example of a solid-state battery half-cell according to an eighth aspect of the invention so made according to an example of the third aspect of the invention;

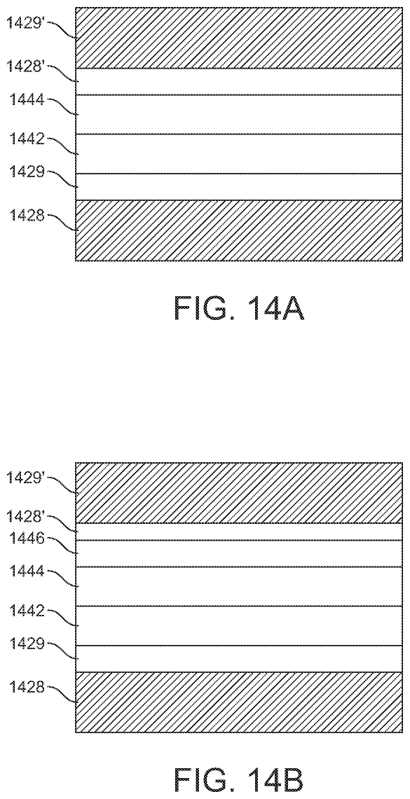

FIG. 14a is a schematic representation of an example of a solid-state battery according to a tenth aspect of the invention so made according to an example of the fifth aspect of the invention;

FIG. 14b is a schematic representation of an example of a solid-state battery according to a tenth aspect of the invention so made according to an example of the fifth aspect of the invention;

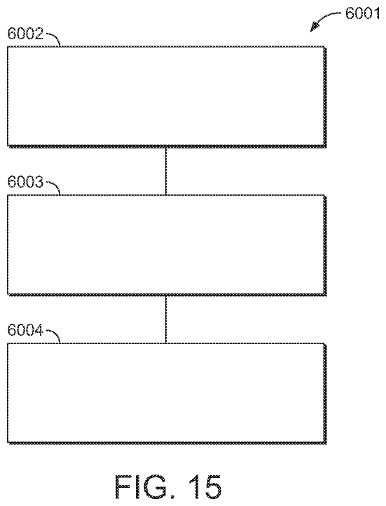

FIG. 15 is a schematic representation of an example of a method of forming a crystalline layer of cathode, optionally for a solid-state battery, on a substrate, in accordance with an eleventh aspect of the invention;

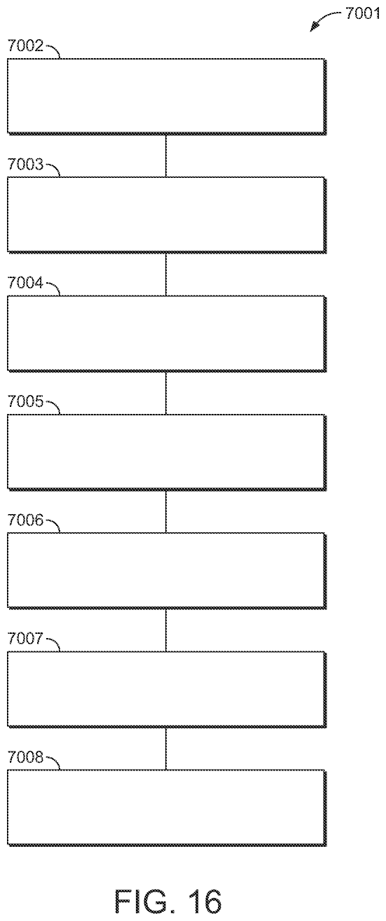

FIG. 16 is a schematic representation of an example of a method of determining a function which describes the crystallinity of a layer of cathode of material as a result of a change in voltage bias applied to a substrate during the deposition of said cathode material, on a substrate, in accordance with an twelfth aspect of the invention;

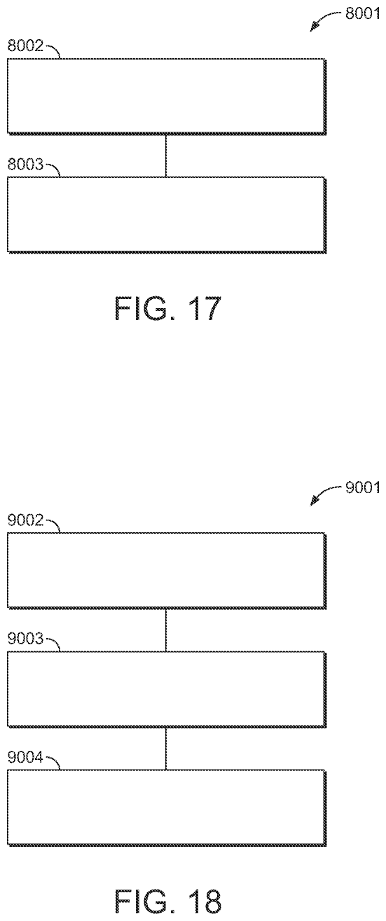

FIG. 17 is a schematic representation of an example of a method of forming a crystalline layer of cathode, in accordance with a thirteenth aspect of the invention;

FIG. 18 is a schematic representation of an example of a method of forming a crystalline layer of cathode optionally for a solid-state battery on a substrate in accordance with an fourteenth aspect of the invention;

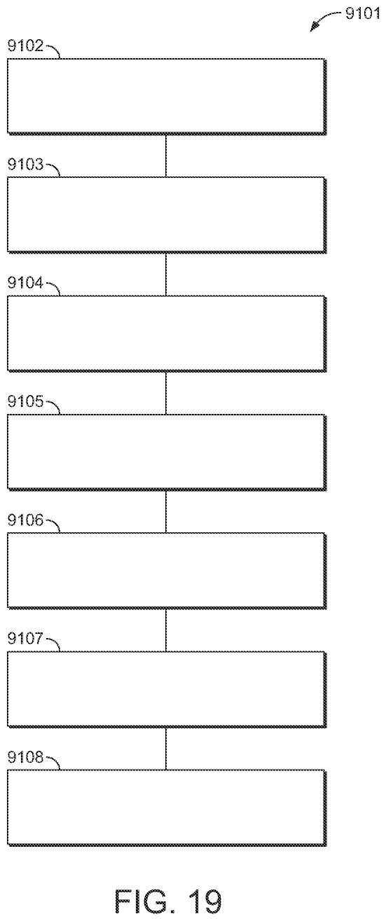

FIG. 19 is a schematic representation of an example of a method of determining a function which describes the phase distribution of a layer of cathode of material in accordance with an fifteenth aspect of the invention;

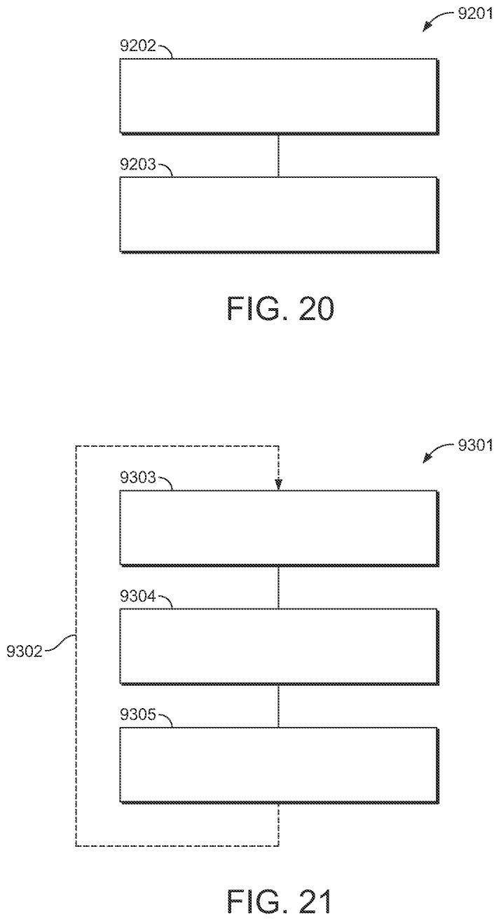

FIG. 20 is a schematic representation of an example of a method of forming a layer of cathode in accordance with a method of the sixteenth aspect of the invention; and

FIG. 21 is a schematic representation of an example of a method of determining the power of a voltage bias at which a higher energy crystal structure would be present in a layer of cathode of material in accordance with a seventeenth aspect of the invention.

### DETAILED DESCRIPTION

FIG. 1a is a schematic side-on view of a plasma deposition process apparatus which is used in a method of depositing a crystalline material onto a substrate to form a layer of cathode in accordance with a first example of the first aspect of the present invention. The method is denoted generally by reference numeral 1001 and is shown schematically in FIG. 1b, and comprises generating 1002 a plasma remote from one or more targets, generating 1003 sputtered material from the target or targets using the plasma, and depositing 1004 the sputtered material on the substrate to which a bias voltage has been applied, thereby forming the layer of cathode. The method of depositing an optionally crystalline layer of cathode onto the substrate may be performed as a part of a method of manufacturing a battery cathode.

The layer of cathode in this first example takes the form ABO₂. In the first example, the ABO₂ material takes a layered oxide structure. In the first example, the ABO₂ material is LiCoO₂. However, the method of the first example has been shown to work on a wide range of ABO₂ materials. In other examples, the ABO₂ material structure comprises at least one of the following compounds (described here with non-specific stoichiometry): LiCoO, LiCoAlO, LiNiCoAlO, LiMnO, LiNiMnO, LiNiMnCoO, LiNiO and LiNiCoO. These materials are potential candidates for manufacturing a battery cathode. Those skilled in the art will realise that the stoichiometry may be varied.

In this first example, the ABO₂ material is LiCoO₂ and is deposited as a layer that is approximately 1 micron thick. In other examples, the ABO₂ material is deposited as layer that is approximately 5 microns or 10 microns thick.

With reference to FIG. 1a, the plasma deposition process apparatus is denoted generally by reference numeral 100 and comprises a plasma target assembly 102 comprising a target 104, a remote plasma generator 106, a series of electromagnets 108 for confining the plasma generated by the remote plasma generator 106, a target power supply 110, a remote plasma source power supply 112 and a housing 114. Remote plasma generator 106 comprises two pairs of radio frequency (RF) antennae 116. Housing 114 comprises a vacuum outlet 120 which is connected to a series of vacuum pumps located outside the chamber so that the chamber 122 defined by housing 114 can be evacuated. Housing 114 is also provided with a gas inlet 124 which may be connected to a gas supply (not shown) for the introduction of one or more gases into the chamber 122. In other examples, the gas inlet 124 may be positioned over the surface of the target assembly 102. As can be seen from FIG. 1a, the plasma is generated remote from the target 104.

In this example, the target 104 comprises LiCoO₂. Briefly, the chamber 122 is evacuated until a sufficiently low pressure is reached. Power provided by power supply 112 is used to power the remote plasma generator 106 to generate a plasma. Power is applied to the target 104 such that plasma interacts with target 104, causing LiCoO₂ to be sputtered from the target 104 and onto the substrate 128. In the present example, the substrate 128 comprises a polymer sheet which is introduced into the housing 114 via inlet 130 and out of the housing 114 via outlet 132. A powered roller 134 is used to help move the substrate 128. The LiCoO₂ is deposited onto the substrate 128 as a crystalline (non-amorphous) material.

The apparatus 100 also comprises a shutter 136, for restricting deposition of sputtered material onto the substrate 128, and an input 138 for cooling the roller 134. Shutter 136 allows a portion of the substrate 128 to be exposed to the sputtered material.

As mentioned above, a powered roller 134 is used to help move the substrate 128 into and out of the plasma deposition apparatus 100. Powered roller 134 is part of a roll-to-roll substrate handling apparatus (not shown) which comprises at least a first storage roller upstream of the plasma deposition apparatus 100 and a second storage roller downstream of the plasma deposition apparatus 100. The roll-to-roll substrate handling apparatus is a convenient way of handling, storing and moving thin, flexible substrates such as the polymer substrate used in this example. Such a roll-to-roll system has a number of other advantages. It allows for a high material throughput and allows a large cathode area to be deposited on one substrate, throughout a series of depositions at a first portion of the substrate, followed by a second portion of the substrate, and so on. Furthermore, such roll-to-roll processing allows for a number of depositions to occur without breaking vacuum. This saves both time and energy compared to systems in which the chamber needs to be taken back up to atmospheric pressure from vacuum after deposition in order to load a new substrate 128. In other examples, sheet-to-sheet processing is used instead of roll-to-roll processing, wherein the substrate 128 is provided with a support. Alternatively, the substrate may be supplied in discrete sheets that are handled and stored in relatively flat sheets. The substrate may be planar in shape as the material is deposited thereon. This may be the case, when the substrate is provided in the form of discrete sheets, not being transferred to or from a roll. The sheets may each be mounted on a carrier, having greater structural rigidity. This may allow for thinner substrates to be used than in the case of substrate film held on a roller. It may be that the substrate is a sacrificial substrate. It may be that the substrate is removed before the layer(s) of material. Part or all of the substrate may be removed before integrating the cathode layer or a part thereof in an electronic product package, component or other end product. For example, the layer of cathode may be lifted off from the substrate. There may be a layer of other intervening material between the base substrate and the crystalline material. This layer may lift off with the layer of cathode or assist in the separation of the layer of cathode from the base substrate. A laser-based lift-off technique may be used. The substrate may be removed by a process that utilises laser ablation. In other examples, another suitable processing regime is used, provided it is capable of sufficiently high production throughput.

The polymer substrate 128 is under tension when moving through the system, for example withstanding a tension of at least 0.001N during at least part of the processing. The polymer is robust enough such that when the polymer is fed through the roll-to-roll machine, it does not experience deformation under tensile stress. In this example, the polymer is Polyethylene terephthalate (PET), and the substrate 128 has a thickness of 1 micron or less, in examples the thickness is 0.9 microns. The substrate 128 is pre-coated with a current collecting layer, which is made of an inert metal, which is in this case nickel. The yield strength of the PET film is sufficiently strong that the substrate does not yield or plastically deform under the stresses of the roll-to-roll handling apparatus.

The use of such thin polymer substrates is beneficial because this facilitates batteries with a higher energy density to be manufactured. In other examples, a material, which is not polymeric, is used, providing that it can be manufactured in a sufficiently thin and flexible manner to allow for a high battery density and ease of handling post-deposition. The plasma deposition process and subsequent manufacturing processes are however subject to the technical challenges that working with such thin layers impose.

Before the substrate 128 is so pre-coated, it has a surface roughness that is carefully engineered so as (a) to be great enough to mitigate the undesirable effects that would otherwise result from electrostatic forces (such as increasing the force required to unwind the polymer film from the drum on which it is held) and (b) to be small enough that the roughness does not cause problems when depositing material onto the substrate. In this example, the surface roughness is engineered to be about 50 nm. It will be noted that the product of the thickness of the substrate (0.9 microns) and the surface roughness is 4.5×10⁴ nm² and is therefore less than 10⁵ nm² and less than 5×10⁴ nm² in this example. It has been found that that the roughness needed for easing handling of thin films rises with decreasing thickness. Generally, it has been found that the roughness required to improve handling of thinner substrates (i.e. less than 10 microns, particularly less than 1 micron) increases as the substrate thickness decreases.

The remotely generated plasma is created by the power supplied to the antennae 116 by power supply 112. There is therefore a measurable power associated with that used to generate the plasma. The plasma is accelerated to the target by means of electrically biasing the target 104, there being an associated electrical current as a result. There is thus a power associated with the bias on the target 104. In this first example the ratio of the power used to generate the plasma to the power associated with the bias on the target is 5:2. Note that in this example, the ratio is calculated on the assumption that the power efficiency of the plasma-generating source is taken to be 50%. The power associated with the bias on the target is at least 1 Wcm⁻².

When the LiCoO₂ film is deposited onto the substrate to form the layer of cathode, it forms a crystalline film of LiCoO₂. The crystalline structure which forms onto the substrate is in the R3̅m space group. This structure is a layered oxide structure. This structure has a number of benefits, such as having a high accessible capacity and high rate of charge and discharge compared to the low energy structure of LiCoO₂, which has a structure in the Fd3m space group. Crystalline LiCoO₂ in the R3̅m space group is often favoured for solid state battery applications.

Throughout the plasma deposition process, the temperature of the substrate 128 does not exceed the degradation point of the polymer substrate 128. Moreover, the temperature of the substrate is sufficiently low throughout the deposition process such that the temperature adjusted yield stress of the polymer substrate remains sufficiently high such that the polymer substrate does not deform under the stresses exerted by the roll-to-roll processing machine.

The general shape of the confined plasma made from the remote plasma generator 106 is shown by the dashed lines B in FIG. 1a. The series of electromagnets 108 is used to and confine the plasma to a desired shape/volume.

It should be noted that, whilst in this first example, substrate 128 is fed into the chamber at inlet 130, and exits the chamber at outlet 132, alternative arrangements are possible. For example, the roll or other store upstream of shutter 136 may be inside the process chamber 122. The roll or other store downstream of shutter 136 may be inside or could be stored inside the process chamber 122.

In addition the means 112 of powering the plasma source, may be of RF, (Direct Current) DC, or pulsed-DC type.

In this first example, the target assembly 102 comprises only one target 104. This target is made of LiCoO₂. It should be appreciated that alternative and/or multiple target assemblies may be used, for example, comprising a distinct region of elemental lithium, a distinct region of elemental cobalt, a distinct region of lithium oxide, a distinct region of cobalt oxide, a distinct region of a LiCo alloy, a distinct region of LiCoO₂, or any combination thereof. In other examples, the ABO₂ material may not be LiCoO₂. In these examples, the target assembly or assemblies contain distinct regions of A, distinct regions of B, distinct regions of a compound containing A and/or B, and/or distinct regions containing ABO₂.

For the avoidance of doubt, the target 104 of the target assembly 103 acts as a source of material alone and does not function as a cathode when power is applied to it from the RF, DC or pulsed DC power supply.

The substrate 128, is placed near a charged plate 135. Charged plate 135 is supplied with a voltage bias by an RF voltage generation device (not shown). The voltage bias transfers from the charged plate 135 to the substrate 128. In other embodiments, the voltage is instead applied directly to the roller 134.

The power density associated with the voltage bias of the substrate is simply the power observed as being drawn to power the substrate.

The voltage bias being applied so close to the substrate increases the velocity of the positive sputtered ions in the plasma. It is believed, without wishing to be bound by theory, that an increase in velocity results in an increased arrival force and hence increased “ad-atom” energy. The end result is improved crystallinity in a film that is deposited on the substrate, compared to a film deposited onto a substrate where a voltage bias is not applied.

The power associated with the voltage bias applied to the substrate is 600 W. The substrate (or the part of the substrate to which a voltage is applied) has a surface area of 177 cm². Therefore, the power density associated with the bias on the substrate is roughly 3.4 Wcm⁻².

The applicant has discovered that the crystallinity of a layer of cathode increases with increased voltage bias applied to the substrate. By this, what is meant is that the layer of cathode has an improve crystallinity compared to a layer of cathode formed under substantially the same process conditions as the present example, wherein there is no voltage bias applied to the substrate.

Assessment of crystallinity as a function of bias power was assessed by measuring the FWHM of an x-ray reflection obtained from a layer of cathode as a function of the bias power applied to the substrate. In this connection, FIG. 2a shows Full Width at Half Maximum (FWHM) values of the (003) reflection in X-ray diffraction patterns obtained from cathode layers deposited using the example methods of the present invention as a function of the measure power associated with the voltage bias applied to the substrate. All samples were deposited using a working distance of 9 cm. The structure of each layer of cathode deposited was characterised by X-ray diffraction using a diffractometer (Panalytical-Empyrean) with CuKα radiation (λ=1.5406 Å) equipped with a Pix3D detector. The diffraction pattern was taken at room temperature in the range 12-100° 2θ. Data were collected using continuous scans with a resolution of 0.02°/step and a count time of 100 s/step.

The (003) reflection is a characteristic reflection from LiCoO₂ when in its hexagonal structure, which is part of the R3̅m space group. The absolute FWHM was measured in relation to this peak for each of the examples 210 220 230 deposited. Those skilled in the art will realise that the absolute Full Width at Half Maximum value comprises an instrument component that is derived from the specific characterisation parameters used during the collection of the X-ray diffraction pattern, and a sample component that is derived from the material properties of the sample being measured. Those skilled in the art would realise that it would also be possible to deconvolute the instrument component from the absolute FWHM.

For the avoidance of doubt, the FWHM is the width of the diffraction peak measured between those points on the y-axis which are half the maximum intensity measured from baseline. The Full Width at Half Maximum values measured for these examples 210 220 230 shown in FIG. 2a are absolute Full Width at Half Maximum values i.e. without the instrument component having been deconvoluted.

The FWHM of a diffraction peak is inversely proportional to the size of sub-micrometre crystallites in a solid. As the skilled person would be well aware, this relationship can be described by the Scherrer equation, which also takes into account instrument parameters that may affect the broadening of an X-ray diffraction peak. A large number of factors contribute to the width of a diffraction peak (other than instrument parameters and crystallite size) which relate to the structure of the material. These structural sources of peak broadening are include inhomogeneous strain, and crystal lattice imperfections such as dislocations, twinning, stacking faults, grain boundaries, and others not listed here. These and other imperfections may also result other peak shape effects, for example asymmetry of a peak. If all of these other contributions to the peak width, including instrumental broadening, were zero, then the peak width would be determined solely by the crystallite size. However in reality, the contributions to the width are non-zero, and the crystallite size can be larger than that inferred by FWHM values, with the “extra” peak width coming from the structural factors previously described. Crystallinity, as a concept, can be used to collectively describe the effect of crystal size and imperfections (such as dislocations, stacking faults, etc.) on peak broadening. As previously stated, crystallinity refers to the degree of structural order in a solid. Therefore, a smaller FWHM value infers that there are fewer of these structural imperfections in the material, and that the material has a higher degree of crystallinity.

FIG. 2a shows that there is an inverse relationship between the power associated with the voltage bias applied to the substrate and the FWHM of the (003) reflection obtained from the layer deposited using said bias voltage on the substrate. As the power associated with the bias voltage is increased, the FWHM of the (003) reflection decreases in an approximately linear manner as shown by dotted line 250.

The FWHM as a function of applied power associated with a bias voltage may be compared to the FWHM when no bias voltage is applied to the substrate to provide a rationalised FWHM, the rationalised FWHM being the FWHM at a particular applied power divided by the FWHM when no power is applied to the substrate. In this connection, FIG. 2c shows a plot of a rationalised Full Width at Half Maximum as a function of applied power used to deposit the cathode layer. As for previous examples described, the reflection from which Full Width at Half maximum values were obtained was the (003) reflection. FIG. 2b shows the Full Width at Half maximum values obtained from layers of cathode deposited using examples of methods of the present invention 215 225 235 245 255 265. Here, the layers of cathode were deposited at a working distance of 14 cm. The FWHM of the (111) peak was measured. There is a linear trend showing a reduction in absolute Full Width at Half Maximum (and thus an increase in crystallinity) as the power associated with the voltage bias applied to the substrate is increased. The applicant has observed that at some working distances (such as 14 cm), there may be effectively an upper limit in the voltage bias applied to the substrate, above which the reduction in Full Width at Half maximum is negligible. In the layers of cathode that were deposited by the methods of examples 215 225 235 245 255 265 of the invention, the applicant has discovered that the upper limit on the voltage bias applied to the substrate is 350-400 W, for the particular process parameters of these examples of the invention.

FIGS. 2a and 2b show how the application of a bias voltage to the substrate on which the cathode layer is deposited may cause increased crystallinity of the deposited cathode layer, there being an inverse linear relationship between the power associated with the applied voltage and the crystallinity. The application of a bias voltage may also facilitate the deposition and/or growth of a higher energy phase structure, as will now be discussed. LiCoO₂ can exist in at least two crystal structures, a lower energy crystal structure having a cubic or spinel structure and a higher energy crystal structure having a hexagonal structure. Higher energy crystal structures are more ordered than lower energy crystal structures, which often results in improved electrical properties for the higher energy crystal structure. Additionally, high energy crystal structures often form in layers, where the alkali metal ion is separated from its counter ion. This allows for alkali metal ions to intercalate and de-intercalate easily, which improves the capacity and ease of charging of the battery. An example of such a high energy crystal structure is LiCoO₂ in the R3̅m space group, the benefits of which (compared to a less ordered, cubic structure) have previously been described. High-energy crystal structures normally require a large amount of heat applied to them, to overcome entropic and/or diffusion related barriers to their formation. In thin-film devices, a high energy crystal structure such as this is normally formed by an annealing step that occurs post deposition. For lithium containing compounds, this often requires heating the lithium-containing material to temperatures of about 400° C. in order to promote formation of the high energy crystal structure. This requires a lot of energy and exposes any other materials associated with the lithium-containing material, such as underlying substrates to such temperatures which may not be desirable.

FIG. 3 shows the X-ray diffractions peaks of the (003) reflection of LiCoO₂ of the examples shown in FIG. 2a (the last 2 digits of the reference numeral indicating which example of FIG. 2a the diffraction peak belongs to). The presence of the (003) reflection peak indicates the presence of the hexagonal form of LiCoO₂, which is a high-energy crystal structure. It is understood that the volume fraction of the high energy structure of LiCoO₂ present in the layer of cathode that forms is positively correlated to the area under the reflection peak. Therefore, the layer of cathode formed through the present example 330 of the invention contains more high energy crystal structure than the layer of cathode of the other example 320 of the present invention, or that of the example where no voltage bias was applied to the substrate 310. The applicant has therefore discovered that it is possible to encourage the formation of a higher energy crystal structure by the application of a bias voltage.

FIG. 4 shows how the height of the (003) peak, and therefore the volume fraction of the higher energy crystal phase, varies with the power associated with the applied voltage. The plot follows a distinctive shape, indicating that the height of the (003) peak changes markedly over a relatively small range of power, in this case between about 400 W and 450 W. Below an estimated critical value of about 400-450 W, there is a relatively small amount of the higher energy crystal structure, and above that value, there is a relatively large amount of the higher energy crystal structure. Under different process conditions, for some examples (characterised examples of which are not shown here), the critical value is around 300 W or 350 W (or around 1.97 Wcm⁻²). It should be noted that some of the higher energy crystal structure is typically formed when a bias voltage is applied, even if the power associated with that bias voltage is lower than the critical value. Referring to FIG. 3, the height of a peak of one example 320 carried out with a voltage bias of 300 W, being slightly higher than that of another example 310 where no voltage bias was applied, shows that slightly more of the high energy crystal structure was formed in the example 320 carried out with a voltage bias of 300 W compared to the case where no voltage was applied. Therefore, even below the critical value, in the case where the critical value is the value at which substantially 50% of the volume of the layer of cathode is in the higher energy crystal structure, and substantially 50% of the volume of the layer of cathode is in the low energy crystal structure), the amount of high energy crystal structure that forms, although small, is higher than the amount that formed at lower voltage biases applied to the substrate, or where no voltage bias is applied at all.

A method of forming a layer of cathode optionally for a solid-state battery on a substrate, the layer of cathode comprising deposited material, the deposited material being capable of existing in a lower energy crystal structure and a higher energy crystal structure in accordance with a first example of the second aspect of the invention will now be described with reference to FIG. 5. The method, generally described by reference numeral 2001, comprises generating 2002 a plasma remote from one or more sputter targets, generating 2003 sputtered material from the target or targets using the plasma, and depositing 2004 the sputtered material on the substrate to which a bias voltage has been applied, thereby forming the layer of cathode, the layer of cathode comprising deposited material in the higher energy crystal structure.

An example of the method of the second aspect of the present invention may comprise any of the features described above in relation to examples of the method of the first aspect of the present invention. For example, the substrate, the deposited material, the lower energy crystal structure and the higher energy crystal structure may have the features described above in relation to the method of the first aspect of the present invention. As mentioned above in relation to the second and third examples of the first aspect of the present invention, the bias voltage may be applied to a support on which the substrate rests, or to the substrate itself.

As previously mentioned, the applicant has discovered that applying a voltage bias to the substrate is beneficial because it can increase crystallinity of the deposited substrate and can promote the formation of high energy crystal structures. FIG. 6 shows that an upper limit can exist in relation to the voltage bias applied to the substrate, above which unfavourable oxides can form. In the example of the invention characterised in FIG. 6, the working distance between target and the substrate is 14 cm. In examples where the material being sputtered is LiCoO₂, the unfavourable oxide that may form may be Co(II)O. The upper limit is characterised by a scenario where a method substantially the same as the present invention (wherein the voltage bias applied to the substrate may be greater than any aforementioned upper limit) was used to deposit layers of cathode, which were characterised with X-ray diffraction. In this connection, FIG. 6 shows the FWHM (circles) and position of the (111) reflection (squares) as a function of the power associated with the voltage applied to the substrate. The position of the (111) reflection and the FWHM of the (111) reflection appear to change markedly when a power of more than 350 W is applied to the substrate. In this connection, above 350 W, the position of the (111) peak is lower than at or below 350 W, indicative of the formation of Co(II)O and Li₂O. The increased FWHM above 350 W is also consistent with the formation of a film of Co(II)O and Li₂O. Therefore FIG. 6 shows a clear transition 601 at a substrate power of between 350 W and 400 W, indicating that the upper limit of the power to be applied to the substrate is between 350 W and 400 W when the working distance between the target and the substrate is 14 cm.

The working distance in some examples of the invention is 9 cm. The working distance between the target 104 and the substrate 128 is shorter than the theoretical mean free path of the system.

In other examples, instead of the voltage being applied to charged plates proximal to the substrate, the roller 134 may have a voltage bias applied to it. In other examples, an RF voltage generation device may be configured to apply voltage directly to the substrate 128. In these, or further examples, the ratio of the power used to generate the plasma to the power associated with the bias on the target is greater than 1:1, and no more than 7:2. The power efficiency of the plasma generating source is taken to be 80%. The power associated with the bias on the target is 10 Wcm⁻², or 100 Wcm⁻². The power associated with the voltage bias applied to the substrate is for example 100 W, 300 W or 700 W. The power density associated with the bias on the substrate is for example 0.1 Wcm⁻² or 2.3 Wcm⁻². A normalised power density (i.e. that has been adjusted in view of one or more process parameters of the method, as previously described in this specification.) is used. In alternative examples of the invention, the working pressure of the system is, for example, 0.0020 mBar, 0.0050 mBar or 0.0065 mBar. The theoretical mean free path of the system is, for example 7.5 cm, 10 cm or 15 cm. The working distance between the target 104 and substrate 128 is 8.5 cm, 9.5 cm, or 14 cm.

A second example method of the first aspect of the invention uses the apparatus shown in FIG. 7a. The main differences between the apparatus of FIG. 1a and the apparatus of FIG. 7a will now be described. FIG. 7a shows that instead of the flexible substrate 128 presented in the first example, an inflexible planar glass substrate 728 is used. Furthermore, no shutter is present in this example. The thickness of the glass substrate is in the order of millimetres. A single target 704 is used. A thermal indicator sticker (not shown) was attached to the face of the glass substrate opposite to that on which the cathode material was deposited. The thermal indicator sticker is configured to indicate whether or not the substrate 728 experienced a temperature of 270° C. or more during the plasma deposition process. Substrate 728 is placed on a substrate stage 735, to which is applied a voltage bias supplied from RF generator 737. The voltage bias then passes from the substrate stage 735 to the substrate 728. After deposition, the sticker indicated that the substrate did not experience a temperature of 270° C. or more during the deposition process. The general shape of the plasma is indicated by the area enclosed by the broken line B′ in FIG. 7a.

A third example method of the first aspect of the invention uses the apparatus shown in FIG. 7b. The main differences between the apparatus of FIG. 7a and the apparatus of FIG. 7b will now be described. FIG. 7b shows that instead of the RF generator 737 applying the voltage bias to the substrate stage 735, the RF generator 737′ applies a voltage bias directly to the substrate 728′.

A method of forming a solid state battery half-cell in accordance with a first example of a third aspect of the invention will now be described with reference to FIG. 8. The method, generally described by reference numeral 3001, comprises forming 3002 a layer of cathode in accordance with the method of the first or second aspect of the present invention wherein the layer of cathode is a cathode layer, and depositing 3003 an electrolyte material suitable for a solid state battery cell on the cathode layer.

The material deposited for the electrolyte is lithium phosphorous oxy-nitride (LiPON). The method comprises generating a plasma remote from one or more targets comprising target material (such as Li₃PO₄); exposing the plasma target or targets to the plasma, thereby sputtering material from the target or targets, optionally in a reactive atmosphere comprising nitrogen, thereby forming LiPON on the battery cathode.

The LiPON is deposited in substantially the same way as the ABO₂ materials in the examples of the first and second aspects of the invention, using a remotely-generated plasma. The target material used is Li₃PO₄, with deposition occurring in a reactive nitrogen atmosphere.

A step of depositing 3004 a current collecting material, in this case nickel, onto electrolyte material is also performed.

As an alternative to Li₃PO₄ the target assembly may include a number of targets, with distinct regions of lithium and/or phosphorous containing compounds, elemental lithium, or lithium oxide. The deposition additionally occurs in a reactive oxygen atmosphere. The electrolyte comprises a polymer, or another suitable electrolyte material. The method comprises depositing a polymer onto said battery cathode, or depositing a precursor onto said battery cathode and forming a polymer from the precursor.

An example of a method of forming a solid state battery cell in accordance with a fourth aspect of the invention will now be described with reference to FIG. 9. The method is denoted generally by reference numeral 4001 and comprises forming 4002 a cathodic half-cell in accordance with the third aspect of the present invention and, contacting 4003 anode material suitable for a solid state battery cell on the electrolyte material. The anode is deposited by a convenient method, such as remote plasma sputtering, magnetron sputtering, CVD etc. The anode material is a lithium alloy or a metal, such as lithium or copper.

An example of a method of making a solid-state battery in accordance with a fifth aspect of the invention will now be described with reference to FIG. 10. The method is denoted generally by reference numeral 5001 and comprises repeatedly forming 5002 a layer of cathode of a solid-state battery, depositing 5003 electrolyte material on the layer of cathode; and depositing 5004 anode material on the electrolyte material wherein at least one step of forming a layer of cathode of a solid-state battery comprises a method in accordance with the first or second aspect of the present invention.

An example of a substrate provided with a layer in made in accordance with the method of the first or second aspect of the present invention, in accordance with a sixth aspect of the present invention, shall now be described with reference to FIG. 11. Referring to FIG. 11, reference numeral 1128 is the substrate (in this case PEN) and reference numeral 1129 is the layer of cathode material made in accordance with examples of the method of the first or second aspect of the present invention.

An example of a substrate provided with a layer of cathode of a solid-state thin film device, the layer of cathode being made in accordance with the method of the first or second aspect of the present invention, in accordance with a seventh aspect of the present invention, wherein the layer of cathode is a cathode of a solid state battery, shall now be described with reference to FIG. 12. Referring to FIG. 12, reference numeral 1228 is the substrate and reference numeral 1229 is the layer of cathode material made in accordance with an example of the method of the first or second aspect of the present invention.

An example of a solid-state battery half-cell according to an eighth aspect of the invention so made according to an example of the third aspect of the invention is shown schematically in FIGS. 13a and 13b. Referring to FIG. 13a, which shows a battery cathode 1342 on a substrate 1328 (which in this example comprises a current collecting layer 1329). FIG. 13b additionally shows electrolyte 1344 deposited on top of the battery cathode 1342. The material deposited for the electrolyte 1344 is lithium phosphorous oxy-nitride (LiPON). In some examples, electrolyte 1344 also acts as a current collecting layer.

An example of a solid-state battery according to a tenth aspect of the invention so made according to an example of the fifth aspect of the invention is shown schematically in FIG. 14a. Referring to FIG. 14a, which shows 1428 and 1428′ are substrate materials 1428 1428′, current collecting layers 1429 1429′, cathode layer 1442 in this case, LiCoO₂, and LiPON 1444, which acts as both electrolyte and anode Alternatively, in other examples, the current collector material acts as an anode material.

Alternatively, in a second example, a further anode material may be deposited. This is shown schematically in FIG. 14b. Referring to FIG. 14b, which shows the same components as FIG. 14a, and additionally shows an anode 1446. The schematics relating to examples of the solid state battery of the tenth aspect of the invention may equally be applicable to examples of the solid state battery cell of the ninth aspect of the invention.

An example of a method of forming a crystalline layer of cathode, optionally for a solid-state battery, on a substrate, in accordance with an eleventh aspect of the invention will now be described with reference to FIG. 15. The method is denoted generally by reference numeral 6001 and comprises repeatedly generating 6002 a plasma remote from one or more sputter targets, generating 6003 sputtered material from the target or targets using the plasma, and depositing 6004 the sputtered material on the substrate to which a bias voltage has been applied, thereby forming the crystalline layer, the power density associated with the bias voltage having been determined to provide the crystalline layer of a desired crystallinity.

The relationship between the power density and the desired crystallinity is not known, so the method comprises: generating a plasma remote from one or more sputter targets, sputtering material from the target or targets using the plasma, and depositing the sputtered material on a first portion of substrate to which a bias voltage has been applied, thereby forming a first crystalline layer, the first power density associated with the bias voltage producing the crystalline layer having a first crystallinity; and generating a plasma remote from one or more sputter targets, sputtering material from the target or targets using the plasma, and depositing the sputtered material on a second portion of substrate to which a bias voltage has been applied, thereby forming a second crystalline layer, the second power density associated with the bias producing the second crystalline layer having a second crystallinity, and based on the crystallinity of the first and second crystalline layers, determining a power density to provide a crystalline layer of the desired crystallinity.

The crystallinity is measured using Full Width at Half Maximum values obtained from one or more X-ray diffraction peaks, where the Full Width at Half Maximum values are normalised by de-convoluting any contribution from the X-ray diffraction apparatus (such as may result from finite beam width, detector imperfections etc.). In other examples absolute Full Width at Half maximum values are known, and the steps as described in the previous paragraph are not required.

An example of a method of determining a function which describes the crystallinity of a layer of cathode of material as a result of a change in voltage bias applied to a substrate during the deposition of said cathode material, on a substrate, in accordance with an twelfth aspect of the invention will now be described with reference to FIG. 16. The method is denoted generally by reference numeral 7001 and comprises repeatedly generating 7002 a plasma remote from one or more sputter targets, generating 7003 sputtered material from the target or targets using the plasma, and depositing 7004 the sputtered material on a first portion of substrate to which a bias voltage has been applied, thereby forming a first crystalline layer, the first power density associated with the bias voltage producing the crystalline layer having a first crystallinity; and, generating 7005 a plasma remote from one or more sputter targets, generating 7006 sputtered material from the target or targets using the plasma, and depositing 7007 the sputtered material on a second portion of substrate to which a bias voltage has been applied, thereby forming a second crystalline layer, the second power density associated with the bias producing the second crystalline layer having a second crystallinity, and based on the crystallinity of the first and second crystalline layers, determining 7008 a function which describes the relationship between the power density associated with the bias on the substrate and the crystallinity of the layer of cathode.

The function takes the form of a linear regression function. The function can be used to predict the value of voltage bias, or value of power density associated with the voltage bias on the substrate, required in order to form a layer of cathode with a desired degree of crystallinity or desired Full Width at Half Maximum value.

An example of a method of forming a crystalline layer of cathode, according to an example of a first or second aspect of the invention, in accordance with an thirteenth aspect of the invention, will now be described with reference to FIG. 17. The method is denoted generally by reference numeral 8001 and further includes the steps of selecting 8002 a desired degree of crystallinity, and using the method of the twelfth aspect of the invention to determine 8003 a voltage bias to be applied to the substrate such that the material forms with the desired crystallinity.

An example of a method of forming a crystalline layer of cathode optionally for a solid-state battery on a substrate, the crystalline layer comprising a deposited material, the deposited material being capable of existing in a lower energy crystal structure and a higher energy crystal structure, in accordance with an fourteenth aspect of the invention, will now be described with reference to FIG. 18. The method is denoted generally by reference numeral 9001 and comprises the steps of generating 9002 a plasma remote from one or more sputter targets, generating 9003 sputtered material from the target or targets using the plasma, and depositing 9004 the sputtered material on the substrate to which a bias voltage has been applied, thereby forming the crystalline layer, the power density associated with the bias voltage having been determined to provide the desired lower energy or higher energy crystal structure.

The method includes selecting the lower energy or higher energy crystal structure and based on said selection, determining the power density associated with the bias voltage required to provide the selected lower energy or higher energy crystal structure. The layer of cathode has substantially all of its volume being the high energy crystal structure.

The relationship between the power density and the crystal structure is not known, and the method additionally comprises depositing a first crystalline layer using a bias voltage associated with a first power density and determining the crystal structure of the first crystalline layer, and depositing a second crystalline layer using a bias voltage associated with a second power density and determining the crystal structure of the second crystalline layer, the second power density being different from the first power density, and based on the crystal structures of the first and second crystalline layers, determining a power density to provide a crystalline layer of the desired lower energy or higher energy crystal structure.

The method comprises generating a plasma remote from one or more sputter targets, sputtering material from the target or targets using the plasma, and depositing the sputtered material on a first portion of substrate to which a bias voltage has been applied, thereby forming a first crystalline layer, and determining the crystal structure of the first crystalline layer; and generating a plasma remote from one or more sputter targets, sputtering material from the target or targets using the plasma, and depositing the sputtered material on a second portion of substrate to which a bias voltage has been applied, thereby forming a second crystalline layer, and determining the structure of the second crystalline layer, and based on the structures of the first and second crystalline layers, determining a power density to provide the desired lower or higher energy crystal structure.

In other examples, the layer of cathode may have a volume of high energy crystal structure, and a volume of low energy crystal structure, where the layer cathode has a higher volume of high energy crystal structure than low energy crystal structure. In some examples, the ratio of the area under the first characteristic peak and the area under the second characteristic peak for the layer of cathode of material directly indicate the volume fraction of the high energy crystal structure in the layer of cathode. For example, in some examples the ratio being 3:1 indicates that 75% of the layer of cathode, by volume, is the high energy crystal structure.

An example of a method of determining a function which describes the phase distribution of a layer of cathode of material, which comprises a volume fraction of a high energy crystal structure and a volume fraction of a low energy crystal structure, as a result of a change in voltage bias applied to a substrate during the deposition of said cathode material in accordance with an fifteenth aspect of the invention, will now be described with reference to FIG. 19. The method is denoted generally by reference numeral 9101 and comprises the steps of generating 9102 a plasma remote from one or more sputter targets, generating 9103 sputtered material from the target or targets using the plasma, and depositing 9004 the sputtered material on a first portion of substrate to which a bias voltage has been applied, thereby forming a first crystalline layer, and determining the crystal structure of the first crystalline layer and generating 9104 a plasma remote from one or more sputter targets, generating 9105 sputtered material from the target or targets using the plasma, and depositing 9106 the sputtered material on a second portion of substrate to which a bias voltage has been applied, thereby forming a second crystalline layer, and determining 9107 the structure of the second crystalline layer and based on the structures of the first and second crystalline layers, determining 9108 a function which describes the relationship between the power density associated with the bias on the substrate and the volume fraction of the high energy crystal structure in the cathode layer.

The function may be used to predict the volume fraction high energy crystal structure will form for a proposed value of voltage bias.

In some examples the ratio of the area under the first characteristic peak and the area under the second characteristic peak is positively correlated to the volume fraction of the high-energy crystal structure in the layer of cathode, wherein the volume fraction of the high energy crystal structure present in the layer of cathode is higher than the volume fraction of the low energy crystal structure when the voltage bias on the substrate is above a critical value, and the method further comprises, initially: selecting a desired volume fraction of high energy crystal structure, and if the desired volume fraction of the high energy crystal structure is higher than half (i.e. higher than 50%), selecting a voltage bias higher than the critical value, and if the desired volume fraction of the high energy crystal structure is lower than half (i.e. lower than 50%), selecting a voltage bias lower than the critical value.

An example of a method of a method of forming a layer of cathode according to the first or second aspect of the invention, in accordance with a method of the sixteenth aspect of the invention, will now be described with reference to FIG. 20. The method is denoted generally by reference numeral 9201 and further comprises the steps of: selecting 9202 a desired volume fraction of high energy crystal structure to be present in the layer of cathode, using 9203 the method of the fifteenth aspect of the invention to determine a voltage bias to be applied to the substrate such that the material forms with the desired volume fraction of high energy crystal structure.

An example of a method of determining the power of a voltage bias at which a higher energy crystal structure would be present in a layer of cathode of material, will now be described with reference to FIG. 21. The method is denoted generally by reference numeral 9301 and comprises repeatedly performing 9302 steps (1), (2) and (3) until a voltage bias is found that results in the formation of the higher energy crystal structure, wherein Step 1 9303 comprises forming a layer of cathode according to the first aspect of the invention, Step 2 9304 comprises performing X-ray diffraction on the layer of cathode, to determine if the high energy crystal structure is present, and Step 3 9305 comprises adjusting the voltage bias to be applied to the substrate before returning to step 1.

Throughout the description, references are made to voltage biases applied to substrates, and power density associated with the voltage bias on a substrate. In many examples discussed in the detailed description, a substrate surface area of 177 cm⁻² was used. Therefore, references to a voltage bias applied to a substrate in the detailed description implicitly refer to a power density associated with a voltage bias applied to a substrate that is the value of the voltage bias applied to the substrate divided by 177 cm⁻². Where a reference is made to a power density associated with the voltage bias on a substrate, that passage of the description implicitly refers to a voltage bias applied to the substrate that is the value of the power density associated with the voltage bias of the substrate multiplied by 177 cm⁻².

Throughout the description, reference is made to the voltage bias applied to a substrate. The measurement associated with the application of a voltage to the substrate is the electrical power applied to the substrate, and that is why the application as filed refers to power associated with the bias voltage.

Throughout the description, references are made to voltage biases applied to substrates. Voltage biases applied to substrates can refer to the case where a voltage bias is applied to the substrate itself directly (i.e. the power supply is directly applied to the substrate), or to a case where a voltage bias is applied to a indirectly, i.e. onto a platform on which the substrate sits, or is otherwise in close proximity to the substrate such that an electrical field is created for accelerating particles to the substrate.

The above examples are to be understood as illustrative examples of the invention. It is to be understood that any feature described in relation to any one example may be used alone, or in combination with other features described, and may also be used in combination with one or more features of any other of the examples, or any combination of any other of the examples. Where in the foregoing description, integers or elements are mentioned which have known, obvious or foreseeable equivalents, then such equivalents are herein incorporated as if individually set forth. It will also be appreciated by the reader that integers or features of the invention that are described as preferable, advantageous, convenient or the like are optional and do not limit the scope of the independent claims. Moreover, it is to be understood that such optional integers or features, whilst of possible benefit in some embodiments of the invention, may not be desirable, and may therefore be absent, in other embodiments. Equivalents and modifications not described above may also be employed without departing from the scope of the invention, which is defined in the accompanying claims.

1. A method of forming a layer of a cathode, optionally for a solid-state battery, on a substrate, the method comprising:
generating a plasma remote from one or more sputter targets,
sputtering material from the target or targets using the plasma, and
depositing the sputtered material on the substrate to which a bias voltage has been applied, thereby forming the layer of cathode.

2. The method according to claim 1, wherein the voltage bias is negative.

3. The method according to claim 1, wherein the voltage bias is supplied by a RF power generator.

4. The method according to claim 1, wherein the power density associated with the voltage bias of the substrate is at least 0.2 Wcm⁻².

5. The method according to claim 1, wherein the power density associated with the voltage bias of the substrate is no more than 3.5 Wcm⁻².

6. The method according to claim 1, wherein the layer of cathode comprises an alkali metal-based or alkaline earth metal based material.

7. The method according to claim 6, wherein the layer of cathode comprises at least one transition metal and a counter-ion.

8. The method according to claim 1, wherein the layer of cathode is selected from the group consisting of: LiCoO₂, LiNiO₂, LiNbO₂, LiVO₂, LiMnO₂, LiMn₂O₄, Li₂MnO₃, LiFePO₄, LiNiCoAlO₂ and Li₄Ti₅O₁₂.

9. The method according to claim 1, wherein the layer of cathode that forms comprises a deposited material, the deposited material being able to exist in a lower energy crystal structure and a higher energy crystal structure, the layer of cathode comprising the deposited material in the higher energy crystal structure.

10. The method according to claim 9, wherein the layer of cathode that forms comprises a volume fraction of the higher energy crystal structure, and optionally a volume fraction of the lower energy crystal structure, wherein the volume fraction of the higher energy crystal structure present in the layer of cathode is higher than the volume fraction of the lower energy crystal structure.

11. The method according to claim 9, wherein the higher energy crystal structure has a characteristic first X-ray diffraction pattern, and the lower energy crystal structure has a characteristic second X-ray diffraction pattern, wherein the first X-ray diffraction pattern comprises a first characteristic peak indicative of the presence of the higher energy crystal structure and the second X-ray diffraction pattern comprises a second characteristic peak indicative of the presence of the lower energy crystal structure.

12. The method according to claim 11, wherein the area under the first characteristic peak is higher than the area under the second characteristic peak.

13. The method according to claim 1, wherein the layer of cathode has a characteristic X-ray diffraction pattern, wherein the X-ray diffraction pattern optionally comprises at least one peak, the at least one peak having a Full Width at Half Maximum (FWHM) value, and wherein the FWHM is from 0.05 to 0.2 degrees.

14. The method according to claim 1, wherein the ratio of the power used to generate the plasma to a power associated with a bias on the target is greater than 1:1.

15. The method according to claim 1, wherein the substrate comprises a flexible substrate.

16. The method according to claim 15, wherein the temperature of the substrate is no more than 200° C.

17. The method of claim 1, wherein the working distance between the target and the substrate is within +/−50% of the theoretical mean free path of the system.

18. The method of claim 1, wherein the process occurs inside a deposition chamber, and a working pressure is defined as the chamber pressure prior to the igniting of the remote plasma, said working pressure being at a substantially constant value throughout the deposition process, said value being between 0.00065 mBar and 1e-2 mBar.

19. The method of claim 18, wherein the sputtering is at least partially caused by bombardment of ions of a sputter gas, and wherein the flow rate of said sputter gas into the chamber is at a substantially constant value throughout the deposition process, said value being between 5 sccm and 200 sccm.

20. A method of forming a layer of cathode optionally for a solid-state battery on a substrate, the layer of cathode comprising deposited material, the deposited material being capable of existing in a lower energy crystal structure and a higher energy crystal structure, the method comprising:
generating a plasma remote from one or more sputter targets,
sputtering material from the target or targets using the plasma, and
depositing the sputtered material on the substrate to which a bias voltage has been applied, thereby forming the layer of cathode, the layer of cathode comprising deposited material in the higher energy crystal structure.

21. A method of forming a solid state battery half-cell, the method comprising:
forming a layer of cathode in accordance with the method of forming a layer of cathode of claim 1; and
depositing an electrolyte material suitable for a solid state battery cell on the cathode layer.

22. A method of forming a solid state battery cell, the method comprising:
forming a solid state battery half-cell in accordance with claim 21; and
contacting anode material suitable for a solid state battery cell on the electrolyte material.

23. A substrate provided with a layer of cathode of a solid-state battery, the layer of cathode being made in accordance with the method of claim 1.

24. A solid-state battery half-cell made in accordance with the method of claim 21.

25. A solid-state battery cell made in accordance with the method of claim 22.

26. A method of forming a crystalline layer of cathode, optionally for a solid-state battery, on a substrate, the method comprising:
generating a plasma remote from one or more sputter targets,
sputtering material from the target or targets using the plasma, and
depositing the sputtered material on the substrate to which a bias voltage has been applied, thereby forming the crystalline layer, the power density associated with the bias voltage having been determined to provide the crystalline layer of a desired crystallinity.

27. A method of determining a function which describes the crystallinity of a layer of cathode of material as a result of a change in voltage bias applied to a substrate during the deposition of said cathode material, comprising;
generating a plasma remote from one or more sputter targets,
sputtering material from the target or targets using the plasma, and
depositing the sputtered material on a first portion of substrate to which a bias voltage has been applied, thereby forming a first crystalline layer, the first power density associated with the bias voltage producing the crystalline layer having a first crystallinity; and
generating a plasma remote from one or more sputter targets,
sputtering material from the target or targets using the plasma, and
depositing the sputtered material on a second portion of substrate to which a bias voltage has been applied, thereby forming a second crystalline layer, the second power density associated with the bias producing the second crystalline layer having a second crystallinity,
and based on the crystallinity of the first and second crystalline layers, determining a function which describes the relationship between the power density associated with the bias on the substrate and the crystallinity of the layer of cathode.

28. A method of forming a layer of cathode on a substrate, the method comprising:
generating a plasma remote from one or more sputter targets;
sputtering material from the target or targets using the plasma;
depositing the sputtered material on the substrate to which a bias voltage has been applied, thereby forming the layer of cathode,
further including the steps of:
selecting a desired crystallinity,
using the method of claim 27 to determine a voltage bias to be applied to the substrate such that the material forms with the desired crystallinity.

29. A method of forming a crystalline layer of cathode, optionally for a solid-state battery, on a substrate, the crystalline layer comprising a deposited material, the deposited material being capable of existing in a lower energy crystal structure and a higher energy crystal structure, the method comprising:
generating a plasma remote from one or more sputter targets,
sputtering material from the target or targets using the plasma, and
depositing the sputtered material on the substrate to which a bias voltage has been applied, thereby forming the crystalline layer, the power density associated with the bias voltage having been determined to provide the desired lower energy or higher energy crystal structure.

30. The method of forming a crystalline layer of cathode according to claim 29, wherein the ratio of the area under the first characteristic peak and the area under the second characteristic peak positively correlated to the volume fraction of the high-energy crystal structure in the layer of cathode, wherein the volume fraction of the high energy crystal structure present in the layer of cathode is higher than the volume fraction of the low energy crystal structure when the voltage bias on the substrate is above a critical value, and the method further comprises, initially:
selecting a desired volume fraction of high energy crystal structure,
if the desired volume fraction of the high energy crystal structure is higher than half (i.e. higher than 50%), selecting a voltage bias higher than the critical value, and if the desired volume fraction of the high energy crystal structure is lower than half (i.e. lower than 50%), selecting a voltage bias lower than the critical value.

31. A method of determining a function which describes the phase distribution of a layer of cathode of material, which comprises a volume fraction of a high energy crystal structure and a volume fraction of a low energy crystal structure, as a result of a change in voltage bias applied to a substrate during the deposition of said cathode material, comprising;
generating a plasma remote from one or more sputter targets,
sputtering material from the target or targets using the plasma, and
depositing the sputtered material on a first portion of substrate to which a bias voltage has been applied, thereby forming a first crystalline layer, and determining the crystal structure of the first crystalline layer; and
generating a plasma remote from one or more sputter targets,
sputtering material from the target or targets using the plasma, and
depositing the sputtered material on a second portion of substrate to which a bias voltage has been applied, thereby forming a second crystalline layer, and determining the structure of the second crystalline layer and,
based on the structures of the first and second crystalline layers, determining a function which describes the relationship between the power density associated with the bias on the substrate and the volume fraction of the high energy crystal structure in the cathode layer.

32. A method of forming a layer of cathode on a substrate, the method comprising:
generating a plasma remote from one or more sputter targets;
sputtering material from the target or targets using the plasma;
depositing the sputtered material on the substrate to which a bias voltage has been applied, thereby forming the layer of cathode,
further including the steps of:
selecting a desired volume fraction of high energy crystal structure to be present in the layer of cathode,
using the method of claim 31 to determine a voltage bias to be applied to the substrate such that the material forms with the desired volume fraction of high energy crystal structure.

33. A method of determining the voltage bias at which a high energy crystal structure would be present in a layer of cathode of material, wherein the method comprises repeatedly performing steps (1), (2) and (3) until a voltage bias is found that results in the formation of the high energy crystal structure, as determined by X-ray diffraction, wherein:
Step (1) comprises forming a layer of cathode according to the method of claim 1,
Step (2) comprises performing X-ray diffraction on the layer of cathode, to determine the if the high energy crystal structure is present, and
Step (3) comprises adjusting the voltage bias to be applied to the substrate before returning to Step (1).
